(19) United States
(12) Patent Application Publication
(10) Pub. No.: US 2026/0206486 A1
(43) Pub. Date: Jul. 16, 2026

(54) PHOTOELECTRIC CONVERSION ELEMENT CONTAINING PHOTOELECTRIC CONVERSION ELEMENT MATERIAL

(71) Applicant: NIPPON STEEL Chemical & Material Co., Ltd., Tokyo (JP)

(72) Inventors: Kentaro HAYASHI, Tokyo (JP); Munetomo INOUE, Tokyo (JP); Kazunari YOSHIDA, Tokyo (JP)

(73) Assignee: NIPPON STEEL Chemical & Material Co., Ltd., Tokyo (JP)

(21) Appl. No.: 19/134,227

(22) PCT Filed: Dec. 18, 2023
(86) PCT No.: PCT/JP2023/045208

§ 371 Date: May 30, 2025

(30) Foreign Application Priority Data
Dec. 23, 2022 (JP) 2022-206604

(51) Int. Cl. H10K 85/60; H10K 30/86; H10K 101/30

(52) U.S. Cl. CPC H10K 85/6572; H10K 30/86; H10K 85/657; H10K 85/6574; H10K 2101/30

(57) ABSTRACT

Provided is a photoelectric conversion device with a photoelectric conversion device material that can achieve higher sensitivity and higher resolution. A photoelectric conversion device having one or two or more organic layers between two electrodes, in which a material for a photoelectric conversion device represented by the following general formula (1) is used in at least one of the organic layers. The ring A and the ring B each represent a fused aromatic group fused with an adjacent ring at any position, such as a carbazole group, X¹ represents, C (Ar¹Ar²), N—Ar³, O, or S, and Ar¹ to Ar³ are each hydrogen, deuterium, a cyano group, a halogen, a nitro group, an alkyl group, an aralkyl group, an alkenyl group, an alkynyl group, an acyl group, an aromatic hydrocarbon group, an aromatic heterocyclic group, or the like.

### TECHNICAL FIELD

The present invention relates to a photoelectric conversion device including a predetermined material for a photoelectric conversion device, and particularly to a photoelectric conversion device useful for an imaging device.

In recent years, development of an organic electronic device using a thin film formed with an organic semiconductor is in progress. Examples thereof include an electroluminescent device, a solar cell, a transistor device, and a photoelectric conversion device. In particular, development of an organic EL device, which is an electroluminescent device with an organic substance, is most advanced among them. The applications for smartphones, TV and the like are in progress, and development for a purpose of further higher functionality is continuously conducted.

Meanwhile, on the photoelectric conversion device for imaging, a device using a P-N junction of an inorganic semiconductor, such as silicon, has been conventionally developed and practically used, and made are investigations for high functionalization of a digital camera and a camera for a smartphone and investigation for application for a monitoring camera, a sensor for an automobile, and the like. However, problems for these various uses include improving sensitivity and micronizing a pixel (improving resolution). For the conventional photoelectric conversion device using an inorganic semiconductor, a mainly adopted method for obtaining a color image is disposing color filters corresponding to RGB, which are the three primary colors of light, on a light receiving part of the photoelectric conversion device. This method has problems in terms of utilization efficiency of an incident light and resolution, because the method disposes the RGB color filters on a plane (Non Patent Literature 1 and 2).

As a solution for such problems of the photoelectric conversion device, a photoelectric conversion device using an organic semiconductor instead of the inorganic semiconductor is developed (Non Patent Literature 1 and 2). This utilizes an ability to selectively absorb only light having a specific wavelength region with high sensitivity that the organic semiconductor has, and proposed is stacking photoelectric conversion devices composed of organic semiconductors corresponding to the three primary colors of light to solve the problem of improving the sensitivity and improving the resolution. A device in which a photoelectric conversion device composed of the organic semiconductor and a photoelectric conversion device composed of the inorganic semiconductor are stacked is also proposed (Non Patent Literature 3).

Here, the photoelectric conversion device composed of the organic semiconductor is a device having a photoelectric conversion layer composed of a thin film of the organic semiconductor between two electrodes, wherein a hole blocking layer and/or an electron blocking layer is disposed, as necessary. In the photoelectric conversion device, light having a desired wavelength is absorbed in the photoelectric conversion layer to generate an exciton, and then charge separation of the exciton generates a hole and an electron. Thereafter, the hole and the electron move toward each electrode to convert the light into an electric signal. For a purpose of accelerating this process, a method of applying a bias voltage between both the electrodes is commonly used, but one of objects is reducing a leakage current from both the electrodes generated by applying the bias voltage. Accordingly, it can be mentioned that controlling the move of the hole and the electron in the photoelectric conversion device is a key to exhibit characteristic of the photoelectric conversion device.

The organic semiconductor used for each layer of the photoelectric conversion device can be classified into a P-type organic semiconductor and an N-type organic semiconductor. The P-type organic semiconductor is used as a hole transport material, and the N-type organic semiconductor is used as an electron transport material. To control the move of the hole and the electron in the photoelectric conversion device, made are various developments of an organic semiconductor having appropriate physical properties such as appropriate hole mobility, electron mobility, energy value of a highest occupied molecular orbital (HOMO), and energy value of a lowest unoccupied molecular orbital (LUMO). However, the organic semiconductor still has insufficient characteristics, and has still not been commercially utilized.

Patent Literature 1 proposes a device using quinacridone as the P-type organic semiconductor and subphthalocyanine chloride as the N-type organic semiconductor for the photoelectric conversion layer, and an indolocarbazole derivative for a first buffer layer disposed between the photoelectric conversion layer and the electrode.

Patent Literature 2 proposes a device using, for the photoelectric conversion layer, a chrysenodithiophene derivative as the P-type organic semiconductor and fullerenes or a subphthalocyanine derivative as the N-type organic semiconductor.

Patent Literatures 3 and 4 propose a device using a carbazole derivative for an electron blocking layer disposed between the photoelectric conversion layer and the electrode.

Patent Literature 5 proposes a device using a pyrene derivative or a triphenylene derivative for an electron blocking layer disposed between the photoelectric conversion layer and the electrode.

Patent Literatures 6 and 7 disclose a polycyclic fused aromatic compound of a structure in which two carbazole rings are fused with a pyrrole ring, but both the Patent Literatures disclose use of the polycyclic fused aromatic compound in an organic EL material, and do not disclose any use thereof in a photoelectric conversion device for imaging.

Patent Literature 8 discloses a polycyclic fused aromatic compound of a structure in which a carbazole ring and a dibenzofuran ring are fused with a pyrrole ring, but discloses use of the polycyclic fused aromatic compound in an organic EL material, and does not disclose any use thereof in a photoelectric conversion device for imaging.

### CITATION LIST

### Patent Literature

### Patent Literature 1

JP 2018-85427 A

### Patent Literature 2

JP 2019-54228 A

### Patent Literature 3

JP 2011-228614 A

### Patent Literature 4

JP 2021-77888 A

### Patent Literature 5

JP 2015-153910 A

### Patent Literature 6

WO 2011/099451

### Patent Literature 7

CN 113717181 A

### Patent Literature 8

WO 2017/038728

### Non Patent Literature

### Non Patent Literature 1

NHK Science & Technology Research Laboratories R&D No. 132, pp. 4-11 (2012.3)

### Non Patent Literature 2

NHK Science & Technology Research Laboratories R&D No. 174, pp. 4-17 (2019.3)

### Non Patent Literature 3

2019 IEEE International Electron Devices Meeting (IEDM), pp. 16.6.1-16.6.4 (2019)

### SUMMARY OF INVENTION

### Technical Problem

For example, in the use of the photoelectric conversion device for imaging for highly functionalizing a digital camera and a camera for a smartphone and for application for a monitoring camera, a sensor for an automobile, and the like, challenges are further higher sensitivity and higher resolution. In view of such a circumstance, an object of the present invention is to provide a material that achieves higher sensitivity and higher resolution of the photoelectric conversion device, and a photoelectric conversion device using the same.

### Solution to Problem

The present inventors have made intensive investigation, and consequently found that using a specific compound efficiently advances a process of generating a hole and an electron by charge separation of an exciton in a photoelectric conversion layer, and a process of moving of the hole and the electron in the photoelectric conversion device. This finding has led to the completion of the present invention.

That is, the present invention relates to a photoelectric conversion device having one or two or more organic layers between two electrodes, wherein at least one of the organic layers comprises a material for a photoelectric conversion device represented by the following general formula (1);

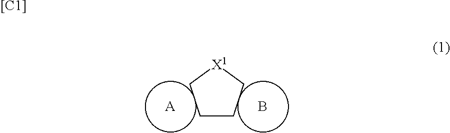

In the general formula (1),
the ring A and the ring B each independently represent an aromatic group fused with an adjacent ring at any position, and represent a substituted or unsubstituted fused aromatic hydrocarbon group having 8 to 20 carbon atoms, or a substituted or unsubstituted fused aromatic heterocyclic group having 10 to 20 carbon atoms,
X¹ each independently represents C (Ar¹Ar²), N—Ar³, O, or S,
Ar¹ to Ar³ each independently represent hydrogen, deuterium, a cyano group, a halogen, a nitro group, an alkyl group having 1 to 20 carbon atoms, an aralkyl group having 7 to 38 carbon atoms, an alkenyl group having 2 to 20 carbon atoms, an alkynyl group having 2 to 20 carbon atoms, an acyl group having 2 to 20 carbon atoms, an acyloxy group having 2 to 20 carbon atoms, an alkoxy group having 1 to 20 carbon atoms, an alkoxycarbonyl group having 2 to 20 carbon atoms, an alkoxycarbonyloxy group having 2 to 20 carbon atoms, an alkylsulfonyl group having 1 to 20 carbon atoms, a substituted or unsubstituted aromatic hydrocarbon group having 6 to 18 carbon atoms, a substituted or unsubstituted aromatic heterocyclic group having 3 to 18 carbon atoms, or a substituted or unsubstituted linked aromatic group in which 2 to 6 aromatic rings are linked.

In the general formula (1), preferably, the ring A is a group represented by general formula (2) and the ring B is a group represented by general formula (3):

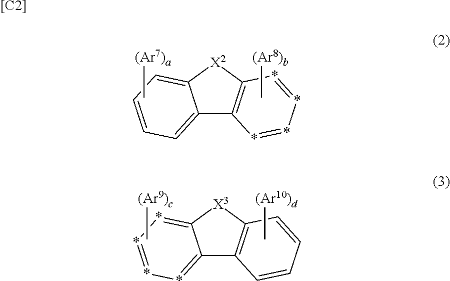

In the general formulae (2) and (3), any side represented by “*” represents a position of fusion with an adjacent ring,
X² and X³ each independently represent C (Ar⁴Ar⁵), N—Ar⁶, O, or S,
Ar⁴ to Ar⁶ are each independently the same as defined for Ar¹ to Ar³,
Ar⁷ to Ar¹⁰ each independently represent deuterium, a cyano group, a halogen, a nitro group, an alkyl group having 1 to 20 carbon atoms, an aralkyl group having 7 to 38 carbon atoms, an alkenyl group having 2 to 20 carbon atoms, an alkynyl group having 2 to 20 carbon atoms, an acyl group having 2 to 20 carbon atoms, an acyloxy group having 2 to 20 carbon atoms, an alkoxy group having 1 to 20 carbon atoms, an alkoxycarbonyl group having 2 to 20 carbon atoms, an alkoxycarbonyloxy group having 2 to 20 carbon atoms, an alkylsulfonyl group having 1 to 20 carbon atoms, a substituted or unsubstituted aromatic hydrocarbon group having 6 to 18 carbon atoms, a substituted or unsubstituted aromatic heterocyclic group having 3 to 18 carbon atoms, or a substituted or unsubstituted linked aromatic group in which 2 to 6 of these aromatic groups are linked,
a to d represent the number of substitutions, a and d each independently represent an integer of 0 to 4, and b and c each independently represent an integer of 0 to 2.

The general formula (1) is preferably represented by any of the following general formulae (4) to (24).

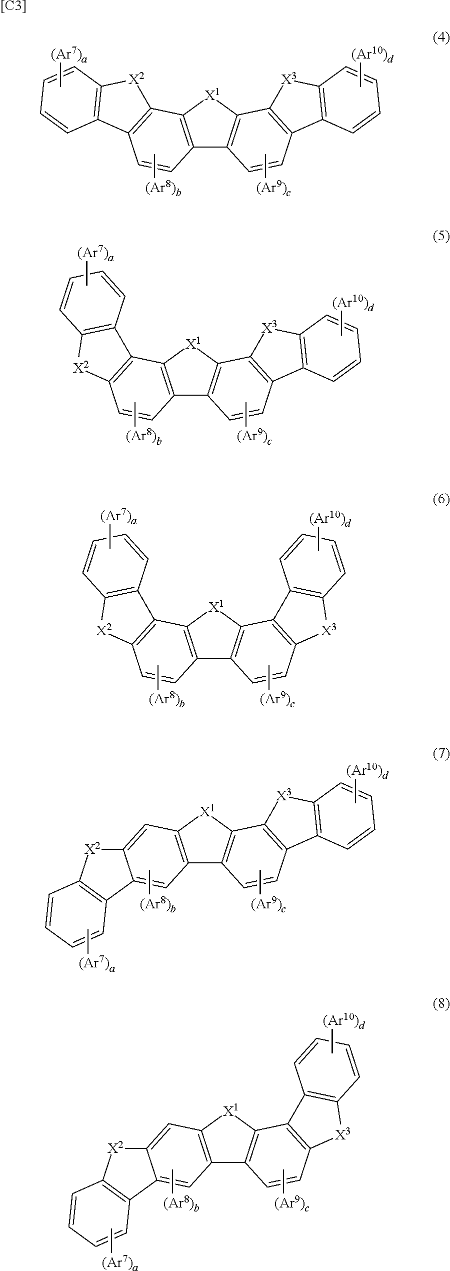

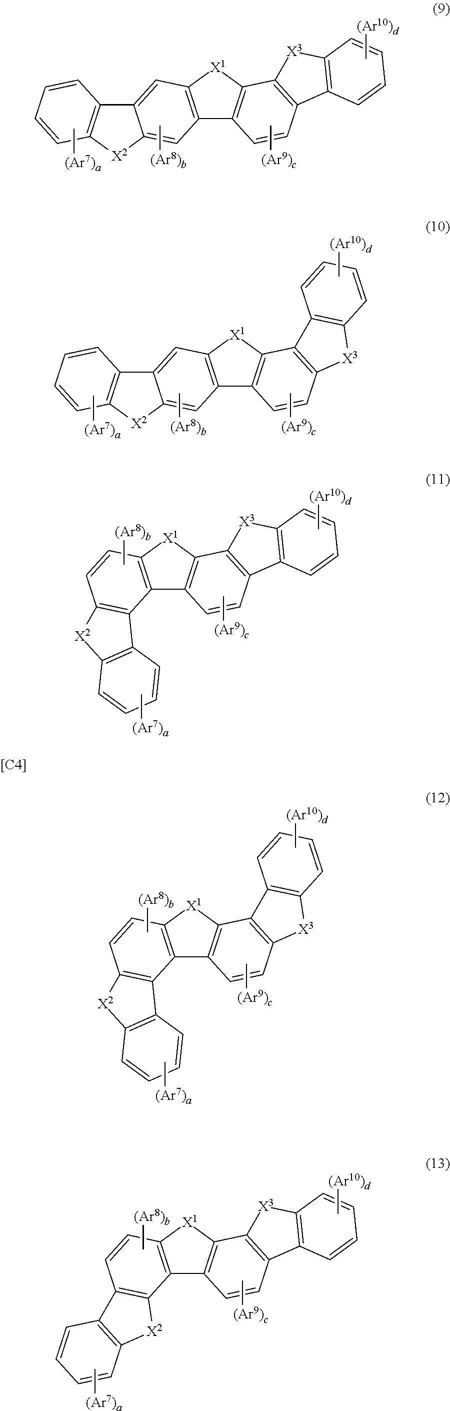

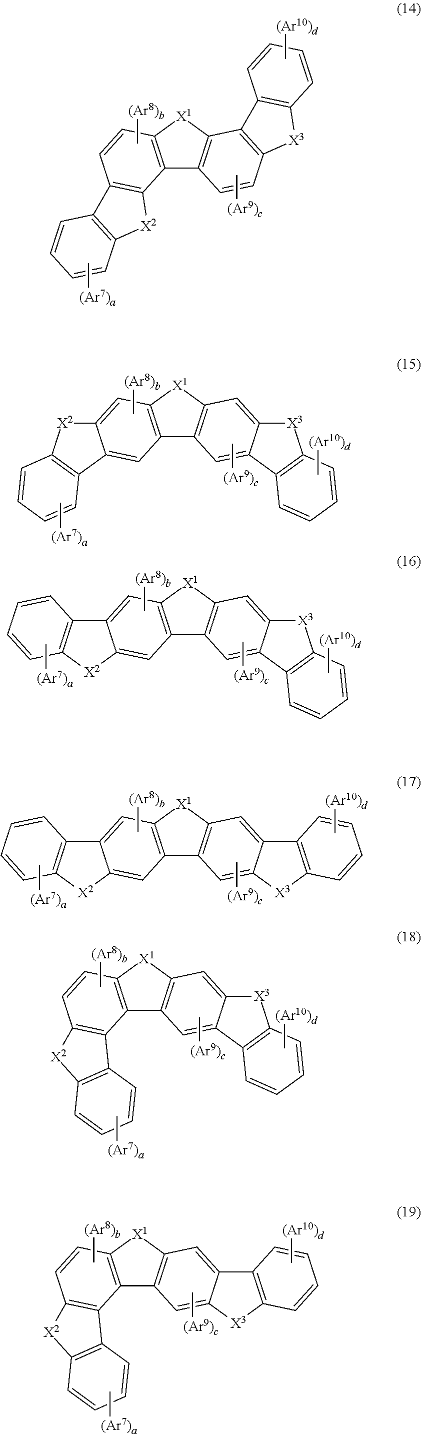

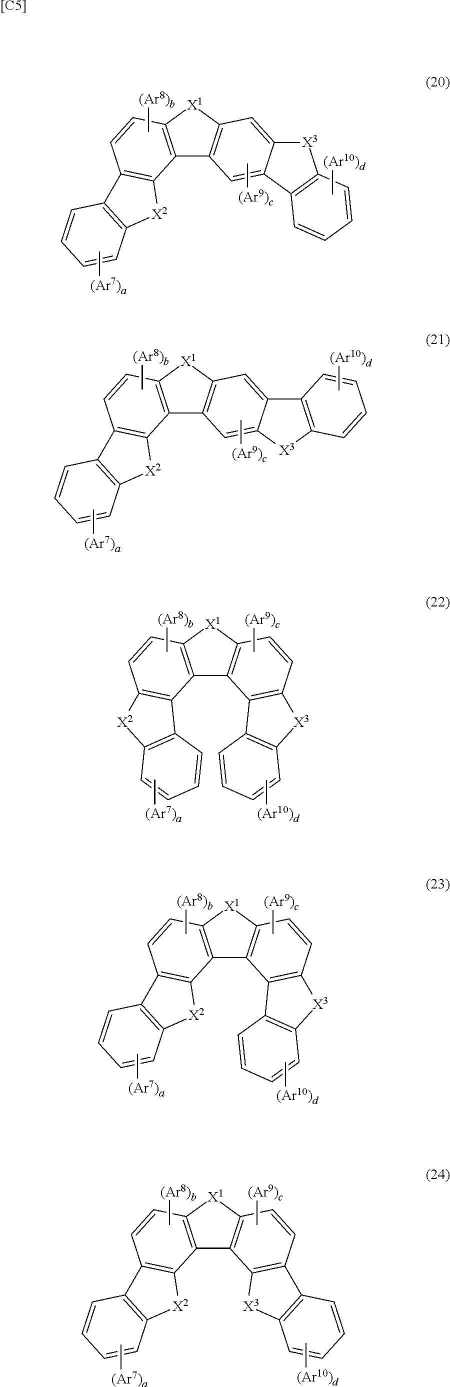

In the general formulae (4) to (24), X¹ to X³, Ar⁷ to Ar¹⁰, and a to d are as defined for the general formulae (1) to (3).

In the general formulae (4) to (24), X¹ to X³ are preferably selected from N—Ar³, N—Ar⁶, O, or S, at least one thereof is more preferably represented by N—Ar³ or N—Ar⁶, two or more thereof are further preferably represented by N—Ar³ or N—Ar⁶, and all of X¹ to X³ are further preferably represented by N—Ar³ or N—Ar⁶.

When two of X¹ to X³ are represented by any one of N—Ar³ or N—Ar⁶, or both thereof, X² and X³ are each independently preferably represented by N—Ar⁶.

In the general formulae (4) to (24), Ar³ and Ar⁶ are each preferably a substituted or unsubstituted aromatic hydrocarbon group having 6 to 18 carbon atoms, a substituted or unsubstituted electron-donating aromatic heterocyclic group, or a substituted or unsubstituted linked aromatic group obtained by linking these, and at least one thereof is preferably a substituted or unsubstituted electron-donating aromatic heterocyclic group, or a substituted or unsubstituted linked aromatic group containing such a group.

The material for a photoelectric conversion device of the present invention preferably has an energy level of highest occupied molecular orbital (HOMO) obtained by structural optimization calculation with a density functional calculation B3LYP/6-31G(d) of −4.0 eV or less and preferably has an energy level of lowest unoccupied molecular orbital (LUMO) obtained by the calculation of-2.5 eV or more.

The material for a photoelectric conversion device of the present invention preferably has a hole mobility of 1×10⁻⁶ cm²/Vs or more, and is preferably amorphous.

The material for a photoelectric conversion device may be used as a hole transport material.

The present invention is a photoelectric conversion device for imaging, comprising a photoelectric conversion layer and an electron blocking layer between two electrodes, wherein at least one layer of the photoelectric conversion layer or the electron blocking layer contains the above material for a photoelectric conversion device.

In the present invention, the material for a photoelectric conversion device represented by the general formula (1) may be contained in the electron blocking layer or the photoelectric conversion layer of the photoelectric conversion device, and is here preferably contained as a hole transport material. The material for a photoelectric conversion device is preferably used in the electron blocking layer. When the material for a photoelectric conversion device is contained in the electron blocking layer, the photoelectric conversion layer may contain an electron transport material, and in particular, preferably contains a fullerene derivative as the electron transport material. Here, the photoelectric conversion layer further contains a material having a backbone containing at least two thiophene rings, as the hole transport material.

In the present invention, when the material for a photoelectric conversion device represented by the general formula (1) is used in the electron blocking layer of the photoelectric conversion device, the absolute value (|h1−e1|), as the difference in energy level between the energy level (h1) of HOMO of the hole transport material used in the photoelectric conversion layer adjacent to the electron blocking layer and the energy level (el) of HOMO of the material for a photoelectric conversion device represented by the general formula (1) contained in the electron blocking layer is preferably 1.0 eV or less, more preferably 0.8 eV or less.

When the material for a photoelectric conversion device represented by the general formula (1) is used in the photoelectric conversion layer of the photoelectric conversion device, the absolute value (|h2−e2|), as the difference in energy level between the energy level (h2) of HOMO of the hole transport material used in the electron blocking layer adjacent to the photoelectric conversion layer and the energy level (e2) of HOMO of the material for a photoelectric conversion device represented by the general formula (1) contained in the photoelectric conversion layer is preferably 1.0 eV or less, more preferably 0.8 eV or less.

When the photoelectric conversion layer contains a plurality of materials, the hole transport material contained in the photoelectric conversion layer refers to a material having a volume fraction of at least 5% or more and having the highest energy level of HOMO among the materials contained in the photoelectric conversion layer.

### Advantageous Effect of Invention

Although the material for a photoelectric conversion device of the present invention can be suitably applied for the photoelectric conversion device for imaging, the material for a photoelectric conversion device of the present invention can also be applied for a sensor converting other optical information into a signal, a solar cell, and the like. Among these, the material for a photoelectric conversion device of the present invention applied for the photoelectric conversion device for imaging can achieve appropriate move of the hole and the electron, and consequently enables to reduce a leakage current generated by applying a bias voltage during the conversion of light into electric energy. As a result, it is considered that a photoelectric conversion device that achieves a low dark current value and a high contrast ratio has been obtained. Therefore, the material of the present invention is useful as a material for a photoelectric conversion device for a photoelectric-converting film-stacked imaging device.

### BRIEF DESCRIPTION OF DRAWING

FIG. 1 is a sectional schematic view illustrating a structure example of a photoelectric conversion device of the present invention.

### DESCRIPTION OF EMBODIMENTS

The photoelectric conversion device in the present invention relates to one having at least one organic layer (namely, one or two or more organic layers) between two electrodes and converting light into electric energy. Specifically, in the present invention, one of such organic layers contains the material for a photoelectric conversion device comprising the compound represented by the general formula (1). Preferably, in the photoelectric conversion device for imaging comprising the photoelectric conversion layer and the electron blocking layer between two electrodes, at least one layer of the photoelectric conversion layer and the electron blocking layer contains the material for a photoelectric conversion device. Hereinafter, the material for a photoelectric conversion device composed of the compound represented by the general formula (1) may be referred to as “material for a photoelectric conversion device of the present invention”, or may be simply referred to as “material for a photoelectric conversion device”, “material of the present invention”, or “compound represented by the general formula (1)”.

The compound represented by the general formula (1) will be described below.

In the general formula (1), the ring A and the ring B each independently represent an aromatic group fused with an adjacent ring at any position, and represent a substituted or unsubstituted fused aromatic hydrocarbon group having 8 to 20 carbon atoms, or a substituted or unsubstituted fused aromatic heterocyclic group having 10 to 20 carbon atoms.

X¹ represents C (Ar¹Ar²), N—Ar³, O, or S.

Examples of the fused aromatic hydrocarbon group having 8 to 20 carbon atoms include groups generated from pentalene, indene, azulene, naphthalene, heptalene, indacene, fluorene, anthracene, phenanthrene, fluoranthene, pyrene, triphenylene, chrysene, tetraphene, tetracene, perylene, corannulene, indenofluorene, and the like.

Examples of the fused aromatic heterocyclic group having 10 to 20 carbon atoms include groups generated from carbazole, dibenzofuran, dibenzothiophene, phenazine, phenoxazine, phenoxathiin, naphthopyrrole, naphthothiophene, naphthofuran, benzocarbazole, naphthobenzofuran, naphthobenzothiophene, indolocarbazole, indenocarbazole, benzofurocarbazole, benzothienocarbazole, benzofurodibenzofuran, benzofurodibenzothiophene, benzothienodibenzofuran, benzothienodibenzothiophene, indenodibenzofuran, indenodibenzothiophene, azacarbazole, azadibenzofuran, azadibenzothiophene, diazacarbazole, diazadibenzofuran, diazadibenzothiophene, and the like.

Preferably, the ring A is a group represented by general formula (2) and the ring B is a group represented by general formula (3).

In the general formulae (2) and (3), any side represented by “*” represents a position of fusion with an adjacent ring. Here, the adjacent ring is a five-membered ring containing X¹, and is fused at a side not containing X¹. X¹ may be fused so as to be in the same direction as or an opposite direction from X² and X³.

X² and X³ each independently represent C (Ar⁴Ar⁵), N—Ar⁶, O, or S.

Ar¹ to Ar³ each independently represent hydrogen, deuterium, a cyano group, a halogen, a nitro group, an alkyl group having 1 to 20 carbon atoms, an aralkyl group having 7 to 38 carbon atoms, an alkenyl group having 2 to 20 carbon atoms, an alkynyl group having 2 to 20 carbon atoms, an acyl group having 2 to 20 carbon atoms, an acyloxy group having 2 to 20 carbon atoms, an alkoxy group having 1 to 20 carbon atoms, an alkoxycarbonyl group having 2 to 20 carbon atoms, an alkoxycarbonyloxy group having 2 to 20 carbon atoms, an alkylsulfonyl group having 1 to 20 carbon atoms, a substituted or unsubstituted aromatic hydrocarbon group having 6 to 18 carbon atoms, a substituted or unsubstituted aromatic heterocyclic group having 3 to 18 carbon atoms, or a substituted or unsubstituted linked aromatic group in which 2 to 6 of these aromatic groups are linked.

In the general formulae (2) and (3), Ar⁴ to Ar⁶ are each independently the same as defined for Ar¹ to Ar³. Ar⁷ to Ar¹⁰ each independently represent deuterium, a cyano group, a halogen, a nitro group, an alkyl group having 1 to 20 carbon atoms, an aralkyl group having 7 to 38 carbon atoms, an alkenyl group having 2 to 20 carbon atoms, an alkynyl group having 2 to 20 carbon atoms, an acyl group having 2 to 20 carbon atoms, an acyloxy group having 2 to 20 carbon atoms, an alkoxy group having 1 to 20 carbon atoms, an alkoxycarbonyl group having 2 to 20 carbon atoms, an alkoxycarbonyloxy group having 2 to 20 carbon atoms, an alkylsulfonyl group having 1 to 20 carbon atoms, a substituted or unsubstituted aromatic hydrocarbon group having 6 to 18 carbon atoms, a substituted or unsubstituted aromatic heterocyclic group having 3 to 18 carbon atoms, or a substituted or unsubstituted linked aromatic group in which 2 to 6 of these aromatic groups are linked.

The compound represented by the general formula (1) is preferably represented by formulae (4) to (24), more preferably represented by any of formulae (4), (6), (15), (22), and formula (24), further preferably represented by any of formulae (4), (15), (22), and formula (24).

In the formulae (4) to (24), X¹ to X³, Ar⁷ to Ar¹⁰, and a to d are as defined for the general formulae (1) to (3).

In the general formulae (1) to (3), X¹ to X³ each represent C (Ar⁴Ar⁵), N—Ar⁶, O, or S, at least one of X¹ to X³ is preferably represented by N—Ar³ or N—Ar⁶, and all of X¹ to X³ are more preferably represented by N—Ar³ or N—Ar⁶.

Similarly, in the formulae (4) to (24), at least one of X¹ to X³ is preferably represented by N—Ar³ or N—Ar⁶, and all of X¹ to X³ are more preferably represented by N—Ar³ or N—Ar⁶.

In the general formulae (1) to (3) and the formulae (4) to (24), Ar³ and Ar⁶ are preferably a substituted or unsubstituted aromatic hydrocarbon group having 6 to 18 carbon atoms, a substituted or unsubstituted electron-donating aromatic heterocyclic group, or a substituted or unsubstituted linked aromatic group in which these groups are linked, and at least one of Ar³ and Ar⁶ is more preferably a substituted or unsubstituted electron-donating aromatic heterocyclic group, or a substituted or unsubstituted linked aromatic group containing such a group.

The unsubstituted electron-donating aromatic heterocyclic group is a π-electron excessive aromatic heterocyclic group, and specific examples thereof include groups generated from dibenzofuran, dibenzothiophene, carbazole, benzothienodibenzothiophene, benzofurodibenzofuran, indolocarbazole, benzofurocarbazole, or benzothienocarbazole.

Ar¹ to Ar⁶ each independently represent hydrogen, deuterium, a cyano group, a halogen, a nitro group, an alkyl group having 1 to 20 carbon atoms, an aralkyl group having 7 to 38 carbon atoms, an alkenyl group having 2 to 20 carbon atoms, an alkynyl group having 2 to 20 carbon atoms, an acyl group having 2 to 20 carbon atoms, an acyloxy group having 2 to 20 carbon atoms, an alkoxy group having 1 to 20 carbon atoms, an alkoxycarbonyl group having 2 to 20 carbon atoms, an alkoxycarbonyloxy group having 2 to 20 carbon atoms, an alkylsulfonyl group having 1 to 20 carbon atoms, a substituted or unsubstituted aromatic hydrocarbon group having 6 to 18 carbon atoms, a substituted or unsubstituted aromatic heterocyclic group having 3 to 18 carbon atoms, or a substituted or unsubstituted linked aromatic group in which 2 to 6 of these aromatic groups are linked. Ar¹ to Ar⁶ preferably represent a substituted or unsubstituted aromatic hydrocarbon group having 6 to 18 carbon atoms, a substituted or unsubstituted aromatic heterocyclic group having 6 to 18 carbon atoms, or a substituted or unsubstituted linked aromatic group in which 2 to 6 of these aromatic groups are linked. When these groups have a hydrogen atom, the hydrogen atom is optionally replaced with deuterium or a halogen.

Ar⁷ to Ar¹⁰ each independently represent deuterium, a cyano group, a halogen, a nitro group, an alkyl group having 1 to 20 carbon atoms, an aralkyl group having 7 to 38 carbon atoms, an alkenyl group having 2 to 20 carbon atoms, an alkynyl group having 2 to 20 carbon atoms, an acyl group having 2 to 20 carbon atoms, an acyloxy group having 2 to 20 carbon atoms, an alkoxy group having 1 to 20 carbon atoms, an alkoxycarbonyl group having 2 to 20 carbon atoms, an alkoxycarbonyloxy group having 2 to 20 carbon atoms, an alkylsulfonyl group having 1 to 20 carbon atoms, a substituted or unsubstituted aromatic hydrocarbon group having 6 to 18 carbon atoms, a substituted or unsubstituted aromatic heterocyclic group having 3 to 18 carbon atoms, or a substituted or unsubstituted linked aromatic group in which 2 to 6 of these aromatic groups are linked. Ar⁷ to Ar¹⁰ preferably represent a substituted or unsubstituted aromatic hydrocarbon group having 6 to 18 carbon atoms, a substituted or unsubstituted aromatic heterocyclic group having 6 to 18 carbon atoms, or a substituted or unsubstituted linked aromatic group in which 2 to 6 of these aromatic groups are linked. When these groups have a hydrogen atom, the hydrogen atom is optionally replaced with deuterium or a halogen.

The alkyl group having 1 to 20 carbon atoms may be any of linear, branched, and cyclic alkyl groups, and is preferably a linear, branched, or cyclic alkyl group having 1 to 10 carbon atoms. Specific examples thereof include: linear saturated hydrocarbon groups, such as a methyl group, an ethyl group, a n-propyl group, a n-butyl group, a n-pentyl group, a n-hexyl group, a n-octyl group, a n-dodecyl group, a n-tetradecyl group, and a n-octadecyl group; branched saturated hydrocarbon groups, such as an isopropyl group, an isobutyl group, a neopentyl group, a 2-ethylhexyl group, and a 2-hexyloctyl group; and saturated alicyclic hydrocarbon groups, such as a cyclopentyl group, a cyclohexyl group, a cyclooctyl group, and a 4-butylcyclohexyl group.

Specific examples of the aralkyl group having 7 to 38 carbon atoms include a benzyl group, a phenethyl group, a phenylpropyl group, a phenylbutyl group, a naphthylmethyl group, and a triphenylenylmethyl group. Specific examples of the alkenyl group having 2 to 20 carbon atoms include an ethylene group, a propylene group, a butylene group, a pentene group, a cyclopentene group, a hexene group, a cyclohexene group, and an octene group. Specific examples of the alkynyl group having 2 to 20 carbon atoms include an acetylene group, a propyne group, a butyne group, and a pentyne group. Specific examples of the acyl group having 2 to 20 carbon atoms include a formyl group, an acetyl group, a propanoyl group, a benzoyl group, and a propenoyl group. Specific examples of the alkoxy group having 1 to 20 carbon atoms include a methoxy group, an ethoxy group, a propoxy group, and a butoxy group.

a to d represent the number of substitutions, and a and d each independently represent an integer of 0 to 4, preferably 0 to 2, more preferably 0 to 1. b and c each independently represent an integer of 0 to 2, preferably 0 to 1, more preferably 0.

When Ar¹ to Ar¹⁰ represent the linked aromatic group, the number of linking is preferably 2 to 6, more preferably 2 to 4.

Examples of the aromatic hydrocarbon group having 6 to 18 carbon atoms include groups obtained by removing one hydrogen from a known aromatic hydrocarbon. Examples of the aromatic hydrocarbon include groups generated from: monocyclic aromatic hydrocarbons, such as benzene; bicyclic aromatic hydrocarbons, such as naphthalene; tricyclic aromatic hydrocarbons, such as indacene, biphenylene, phenalene, anthracene, phenanthrene, and fluorene; and tetracyclic aromatic hydrocarbons, such as fluoranthene, acephenanthrylene, aceanthrylene, triphenylene, pyrene, chrysene, tetraphene, tetracene, and pleiadene. Preferred is phenyl, naphthyl, anthracenyl, triphenylyl or pyrenyl.

Examples of the aromatic heterocyclic group having 3 to 18 carbon atoms include groups obtained by removing one hydrogen from an aromatic heterocyclic group. Examples of the aromatic heterocyclic group include: a group generated from nitrogen-containing aromatic compounds having a pyrrole ring, such as pyrrole, pyrrolopyrrole, indole, pyrroloindole, benzoindole, naphthopyrrole, isoindole, pyrroloisoindole, benzoisoindole, naphthoisopyrrole, carbazole, benzocarbazole, indoloindole, carbazolocarbazole, indolocarbazole, and carboline; sulfur-containing aromatic compounds having a thiophene ring, such as thiophene, benzothiophene, naphthothiophene, dibenzothiophene, benzothienonaphthalene, benzothienobenzothiophene, benzothienodibenzothiophene, dinaphthothiophene, dinaphthothienothiophene, naphthobenzothiophene, and benzothienocarbazole; oxygen-containing aromatic compounds having a furan ring, such as furan, benzofuran, naphthofuran, dibenzofuran, benzofuronaphthalene, benzofurobenzofuran, benzofurodibenzofuran, dinaphthofuran, dinaphthofuranofuran, naphthobenzofuran, and benzofurocarbazole; pyridine, pyrimidine, triazine, quinoline, isoquinoline, quinazoline, and quinoxaline. The aromatic heterocyclic group is preferably dibenzofuranyl, dibenzothienyl, carbazolyl, benzothienodibenzothienyl, benzofurodibenzofuranyl, indolocarbazolyl, benzofurocarbazolyl, or benzothienocarbazolyl.

When Ar¹ to Ar¹⁰ represent the aromatic hydrocarbon group, the aromatic heterocyclic group, or the linked aromatic group, these groups optionally have a substituent. Examples of the substituent include deuterium, an alkyl group having 1 to 20 carbon atoms, a cyano group, an alkylsilyl group, a diarylamino group, an arylheteroarylamino group, and a diheteroarylamino group. The substituent is preferably deuterium, a linear, branched, or cyclic alkyl group having 1 to 10 carbon atoms, a diarylamino group, an arylheteroarylamino group, or a diheteroarylamino group.

Specific examples of the alkyl group having 1 to 20 carbon atoms include: linear saturated hydrocarbon groups, such as a methyl group, an ethyl group, a n-propyl group, a n-butyl group, a n-pentyl group, a n-hexyl group, a n-octyl group, a n-dodecyl group, a n-tetradecyl group, and a n-octadecyl group; branched saturated hydrocarbon groups, such as an isopropyl group, an isobutyl group, a neopentyl group, a 2-ethylhexyl group, and a 2-hexyloctyl group; and a cyclopentyl group, a cyclohexyl group, a cyclooctyl group, a 4-butylcyclohexyl group, and a 4-dodecylcyclohexyl group. The alkyl group having 1 to 20 carbon atoms may be any of linear, branched, and cyclic alkyl group.

Specific examples of the diarylamino group include a diphenylamino group, a phenyl-biphenylamino group, a phenyl-terphenylamino group, a phenyl-naphthylamino group, a phenyl-phenanthrylamino group, and a phenyl-triphenylenylamino group.

Specific examples of the aryl-heteroarylamino group include a phenyl-(9-phenyl-3-carbazolyl)amino group, a phenyl-3-dibenzofuranylamino group, and a phenyl-3-dibenzothiophenylamino group.

Specific examples of the diheteroarylamino group include a di-1-dibenzofuranylamino group, a 3-dibenzofuranyl-3-dibenzothiophenylamino group, and a di-(9-phenyl-1-carbazolyl)amino group,

The diarylamino group, the aryl-heteroarylamino group, and the diheteroarylamino group each serving as the substituent optionally further have a substituent at an aryl moiety and a heteroaryl moiety, and examples of such a substituent include an aryl group or a heteroaryl group. Specific examples of the aryl group as the substituent in such an amino group include a phenyl group, a biphenyl group, a terphenyl group, a quaterphenyl group, a naphthyl group, a phenanthrenyl group, an anthracenyl group, a triphenylenyl group, a pyrenyl group, a fluorenyl group, and a spiro-bifluorenyl group, and the aryl group is preferably a phenyl group, a biphenyl group, a terphenyl group, a naphthyl group, a phenanthrenyl group, a fluorenyl group, or a triphenylenyl group.

Specific examples of the heteroaryl group as the substituent in such an amino group include groups obtained by removing one hydrogen atom from pyrrole, pyrrolopyrrole, indole, pyrroloindole, benzoindole, naphthopyrrole, isoindole, pyrroloisoindole, benzoisoindole, naphthoisopyrrole, carbazole, benzocarbazole, indoloindole, carbazolocarbazole, benzofurocarbazole, benzothienocarbazole, carboline, thiophene, benzothiophene, naphthothiophene, dibenzothiophene, benzothienonaphthalene, benzothienobenzothiophene, benzothienodibenzothiophene, dinaphthothiophene, dinaphthothienothiophene, naphthobenzothiophene, furan, benzofuran, naphthofuran, dibenzofuran, benzofuronaphthalene, benzofurobenzofuran, benzofurodibenzofuran, dinaphthofuran, dinaphthofuranofuran, naphthobenzofuran, pyridine, pyrimidine, triazine, quinoline, isoquinoline, quinazoline, quinoxaline, and the like, and preferably from dibenzofuran, dibenzothiophene, carbazole, benzofurocarbazole, or benzothienocarbazole.

The linked aromatic group herein refers to an aromatic group in which aromatic rings of two or more aromatic groups are bonded and linked with a single bond. These linked aromatic groups may be linear or branched. A linking position in linking the benzene rings each other may be any of ortho, meta, and para, but para-liking or meta-linking is preferable. The aromatic group may be an aromatic hydrocarbon group or an aromatic heterocyclic group. The plurality of the aromatic groups may be same as or different from each other.

Preferable specific examples of the compound represented by the general formula (1) are shown below, but the compound is not limited thereto.

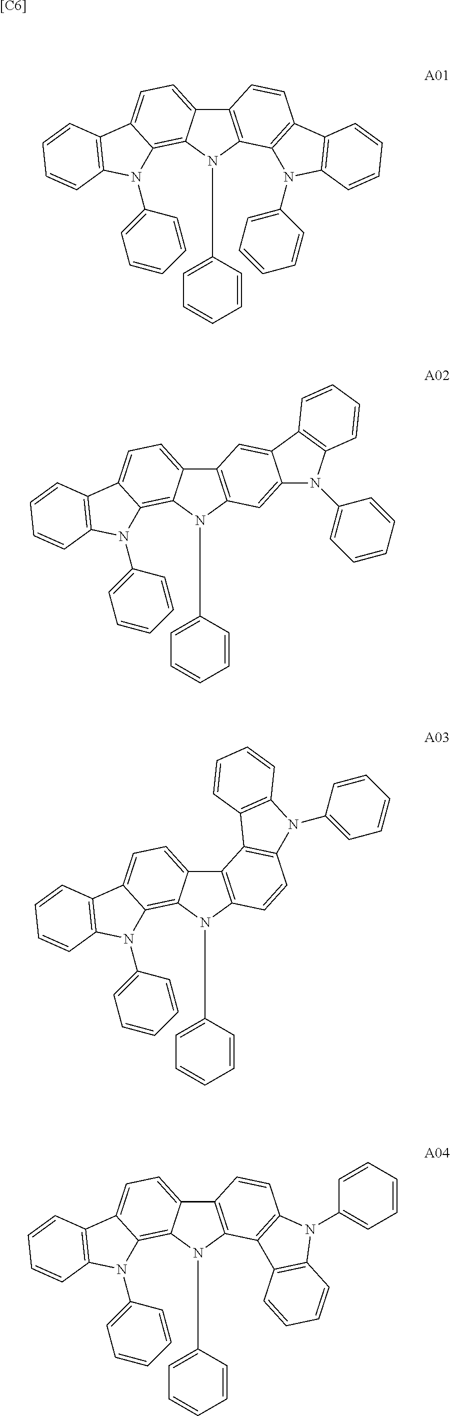

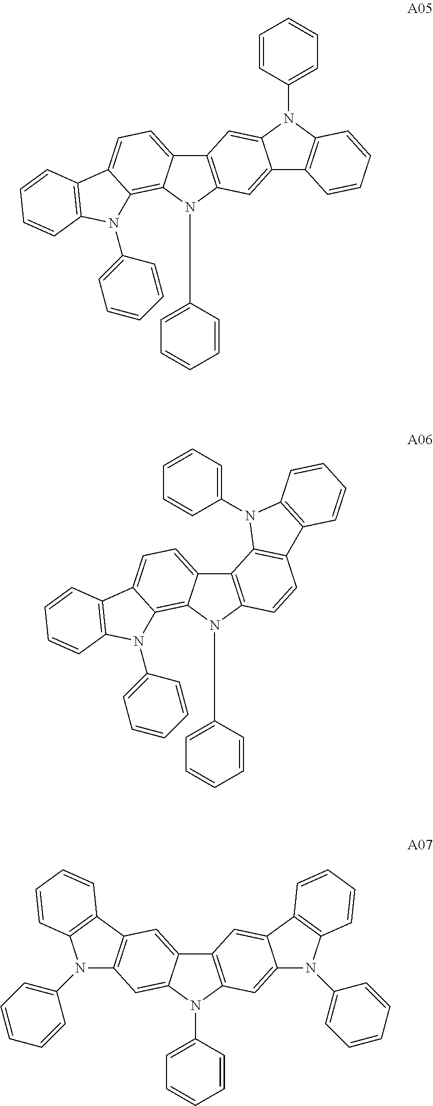

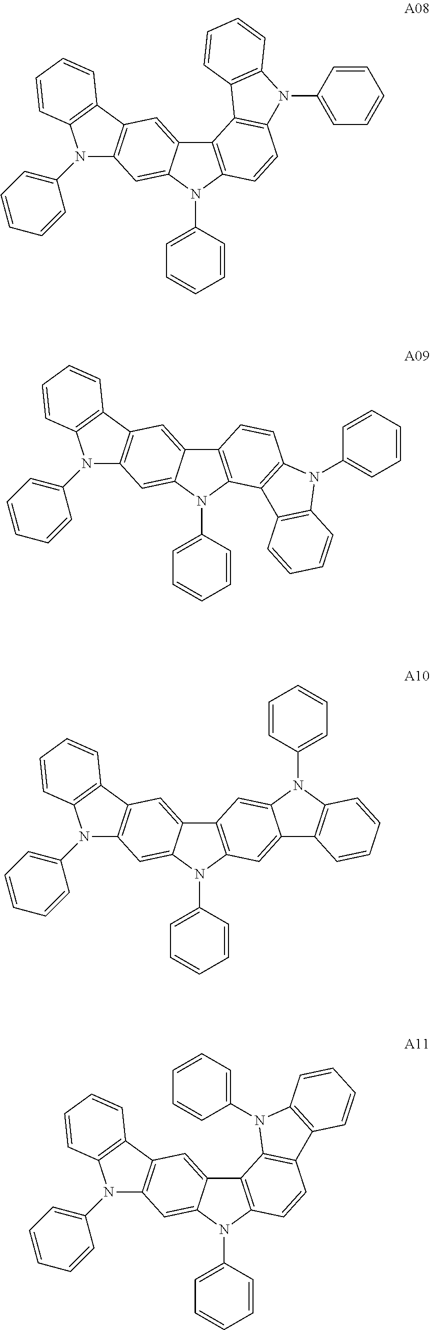

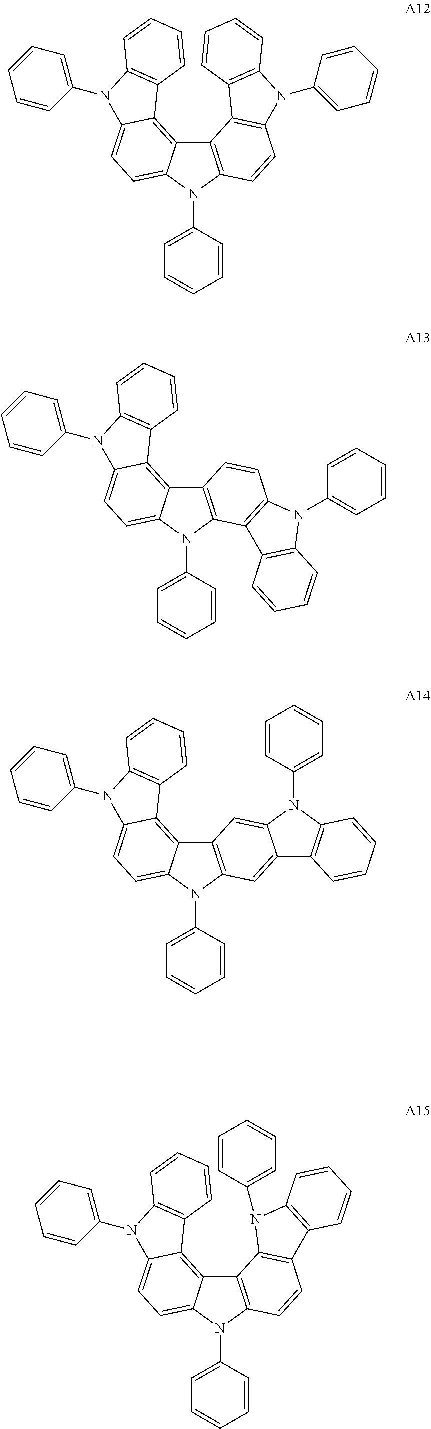

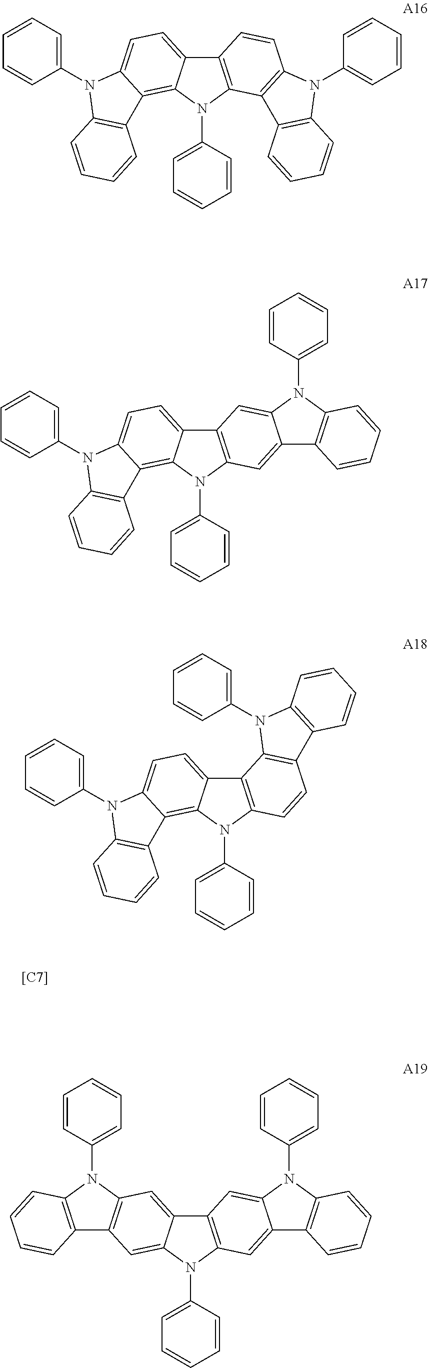

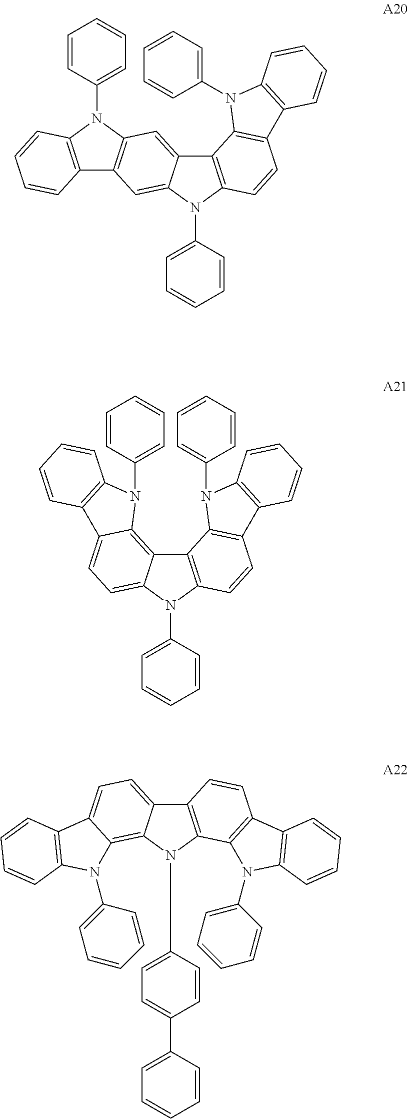

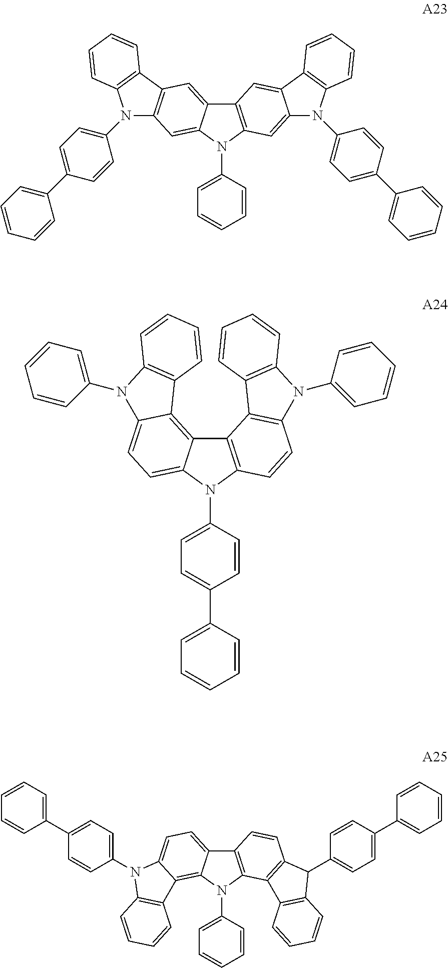

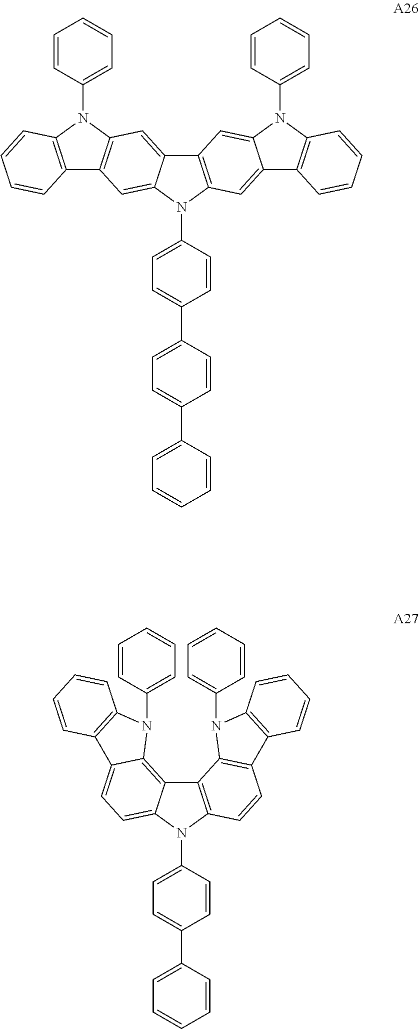

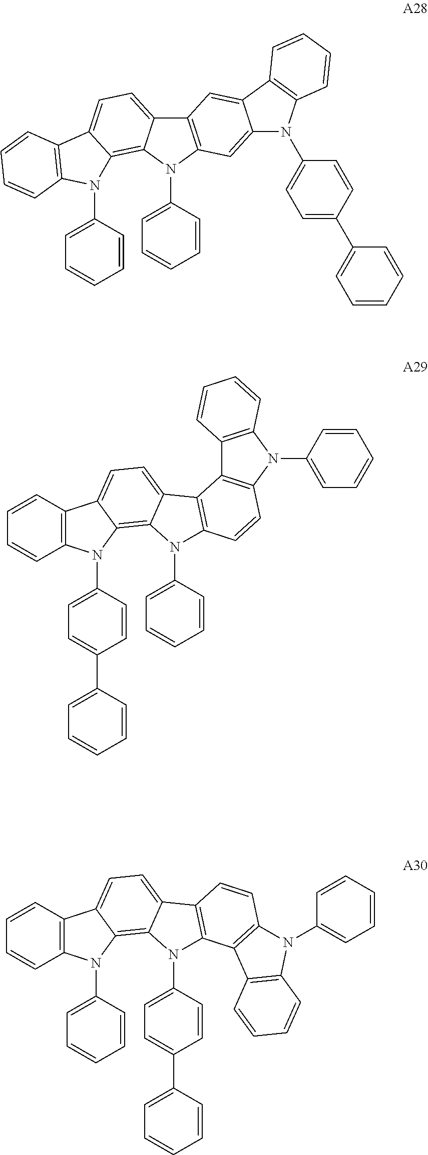

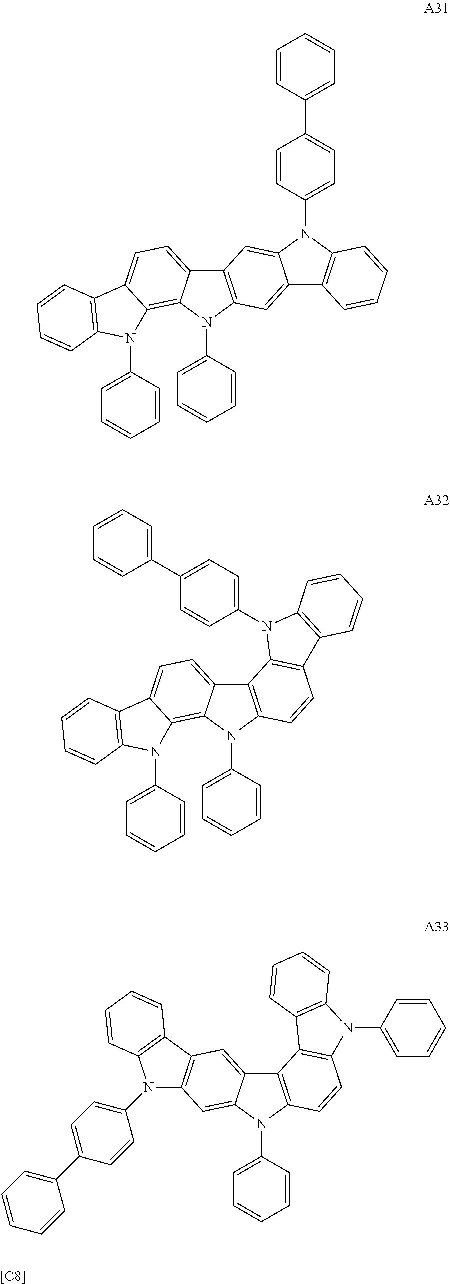

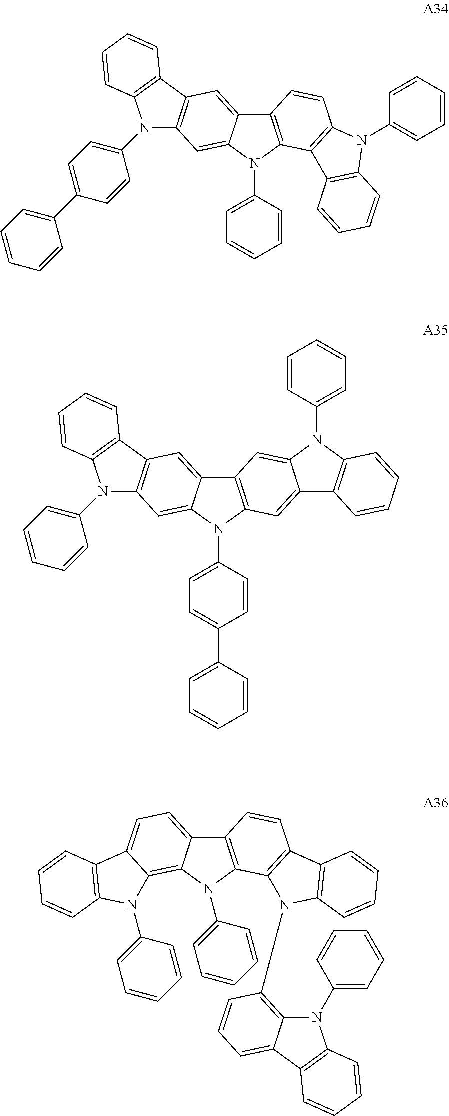

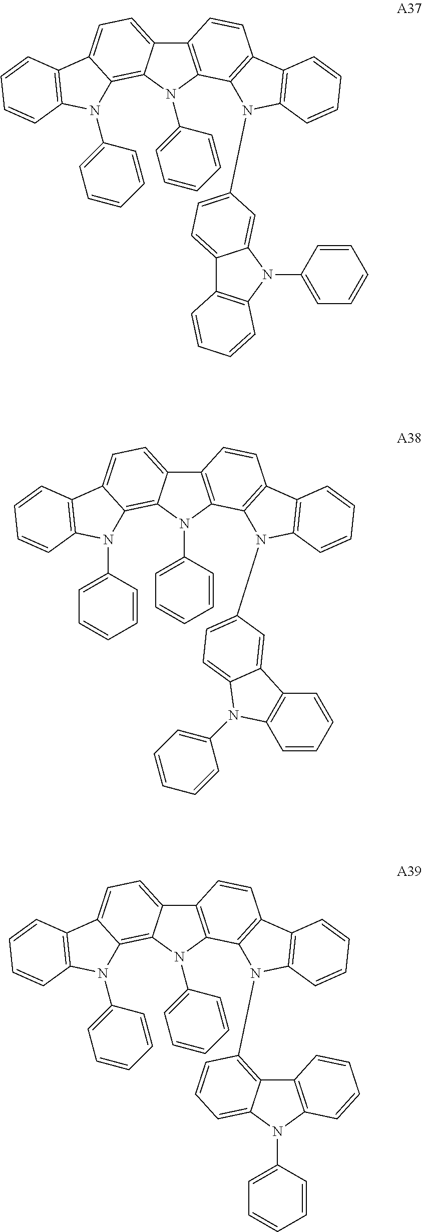

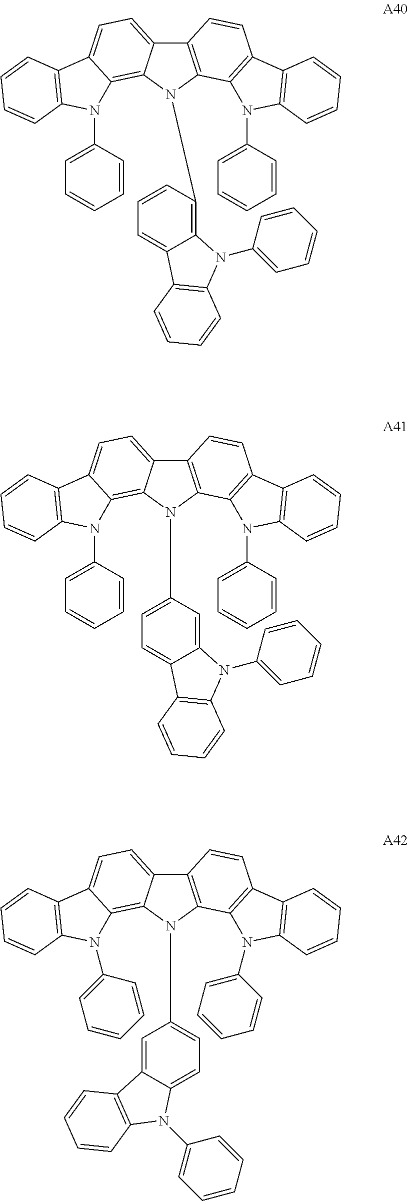

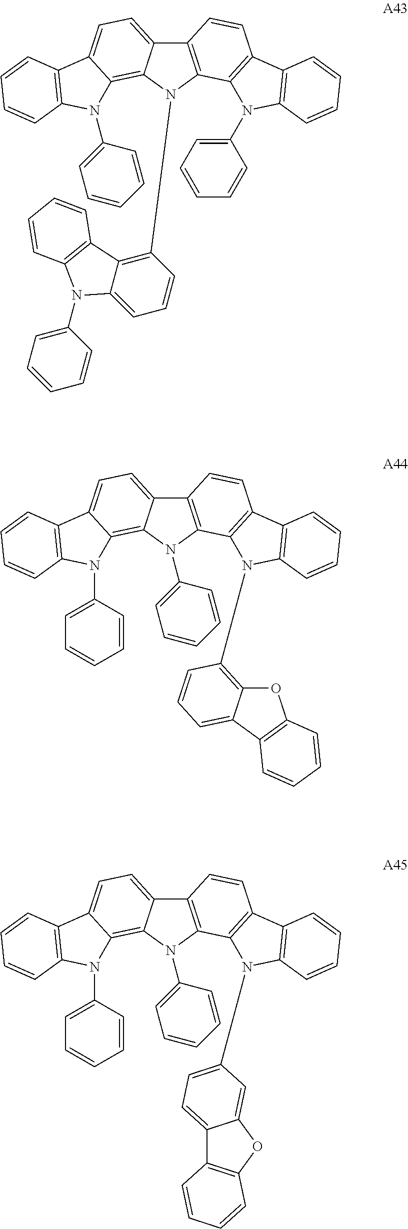

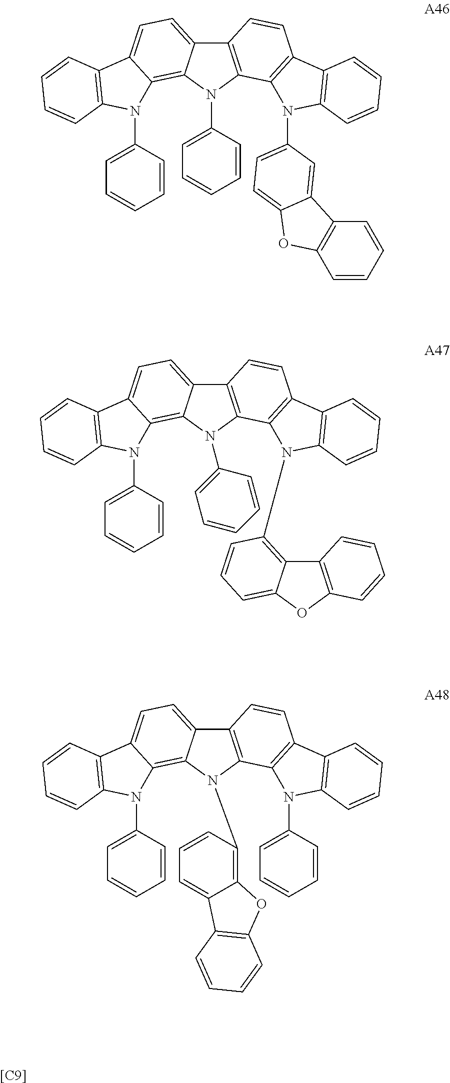

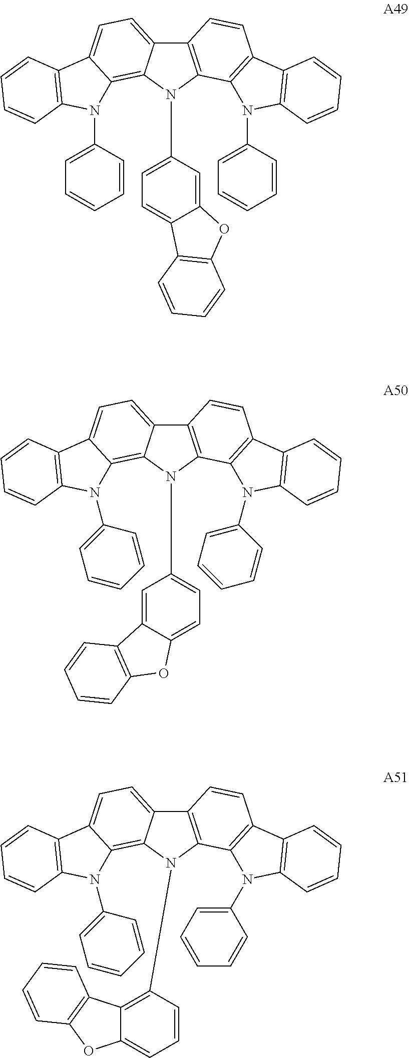

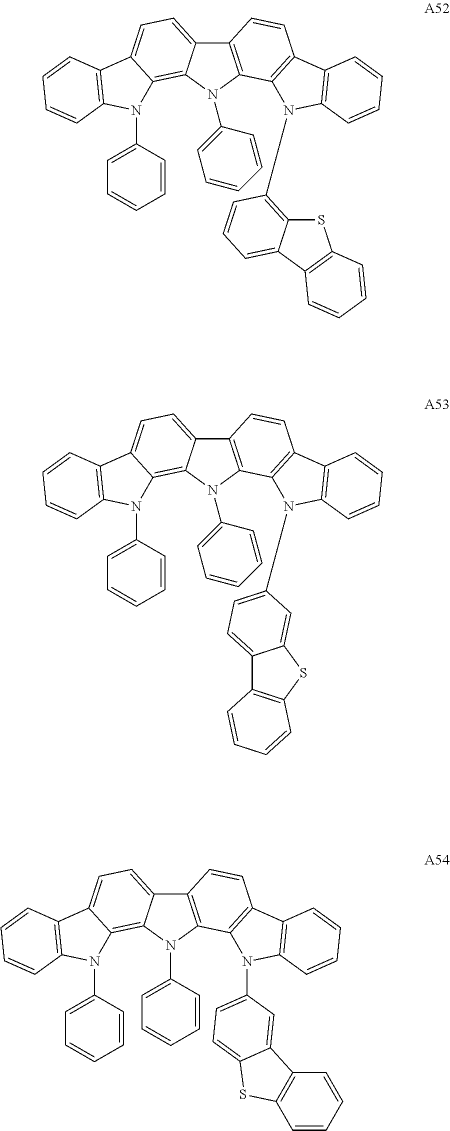

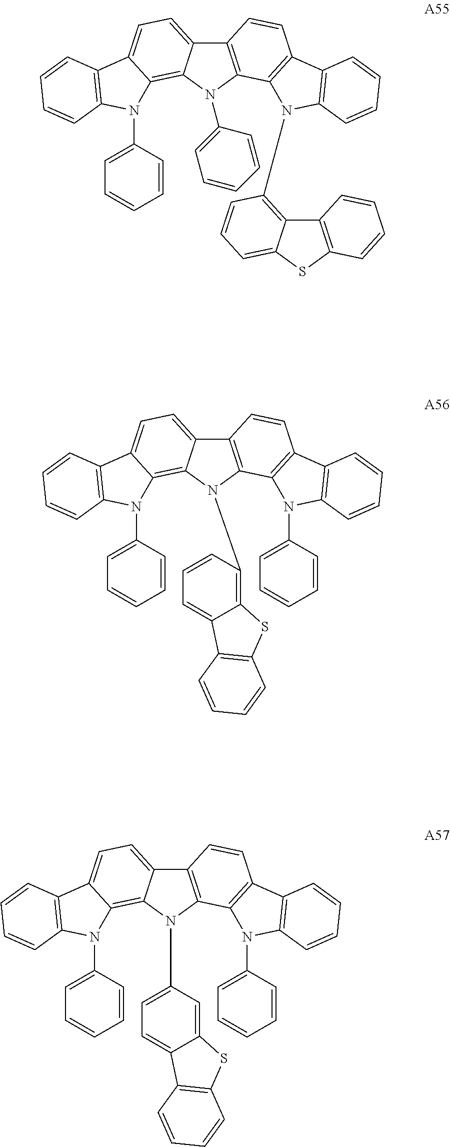

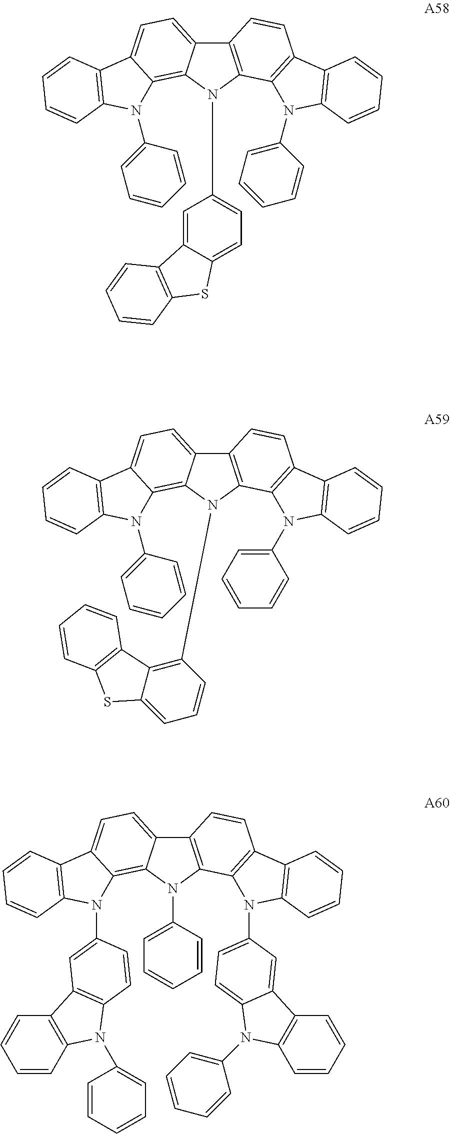

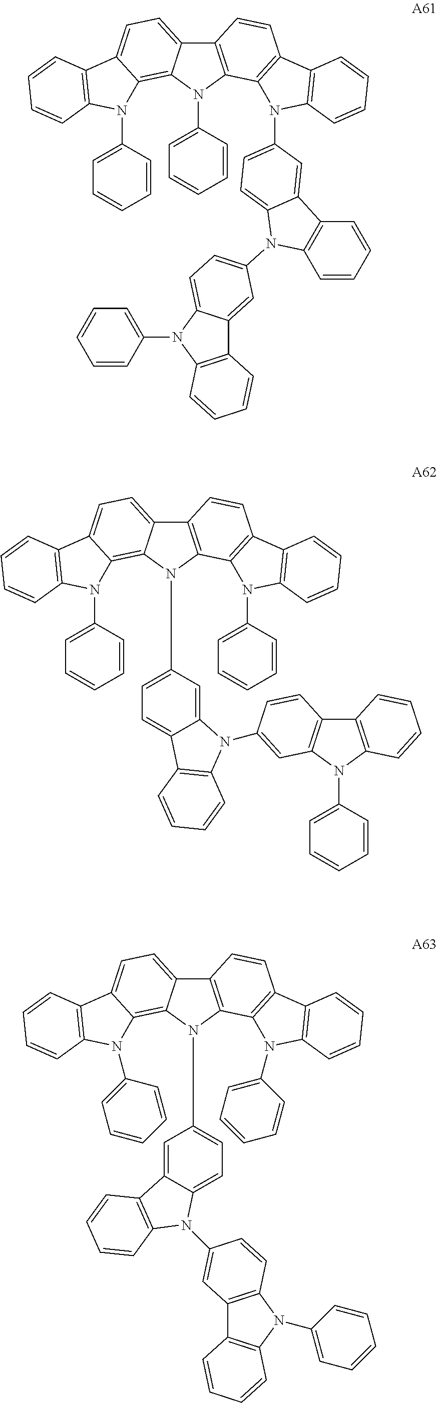

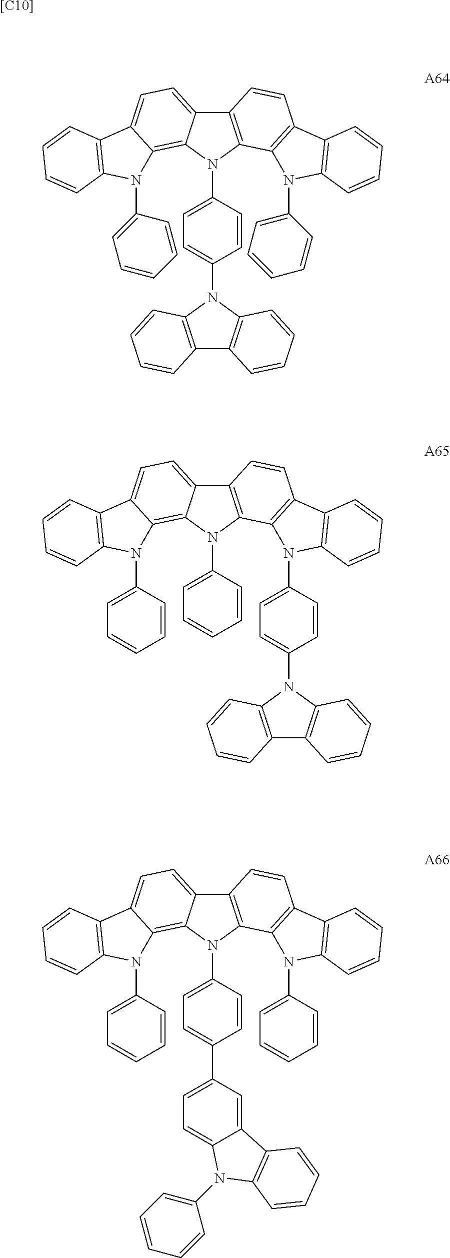

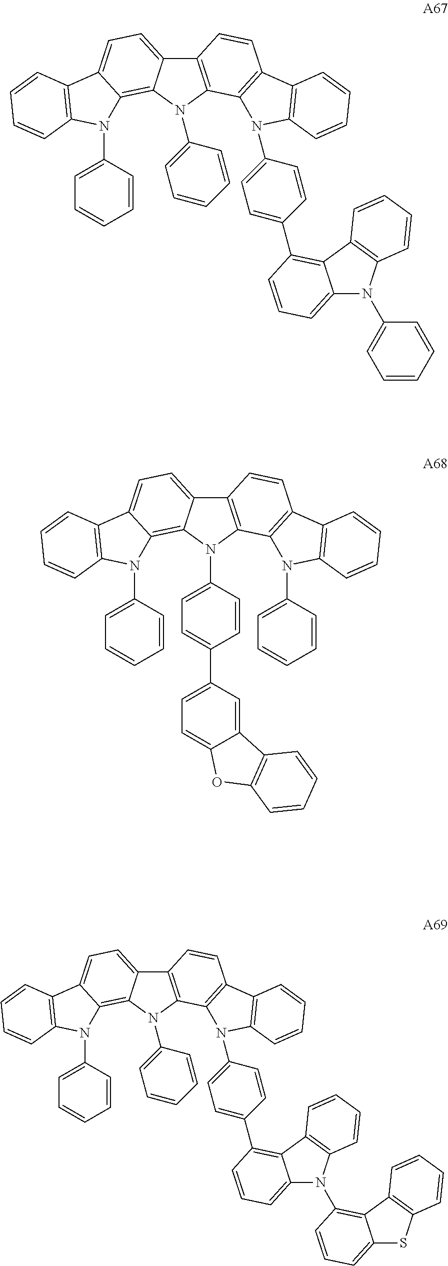

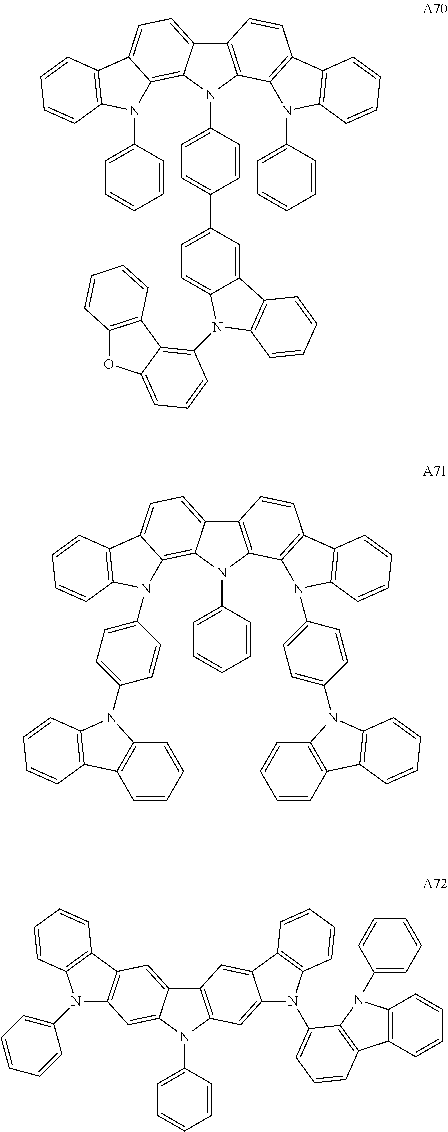

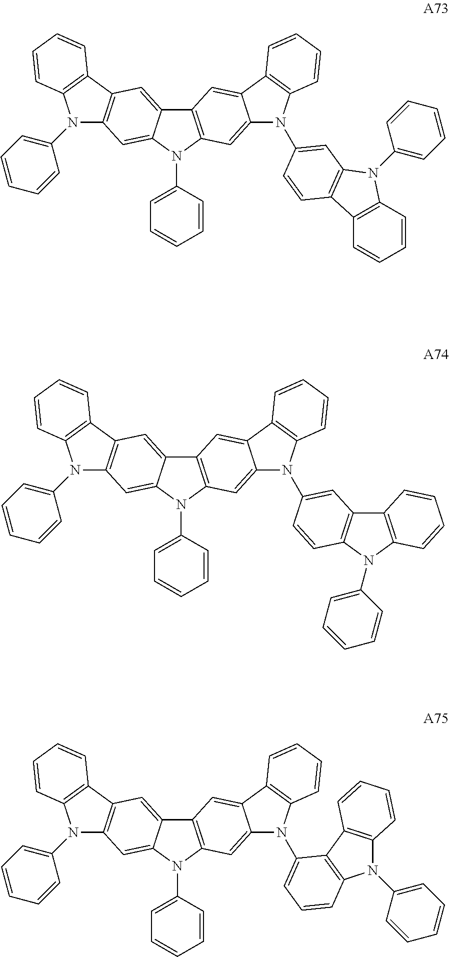

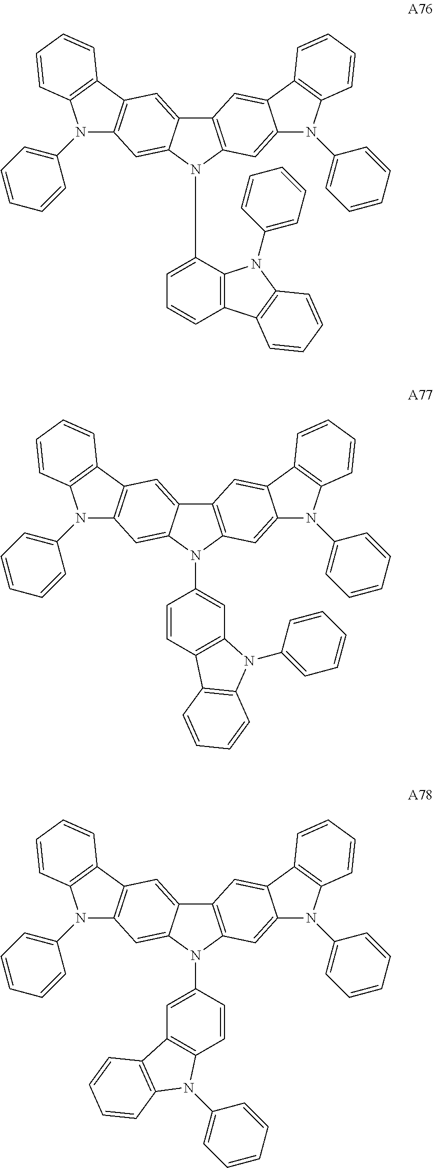

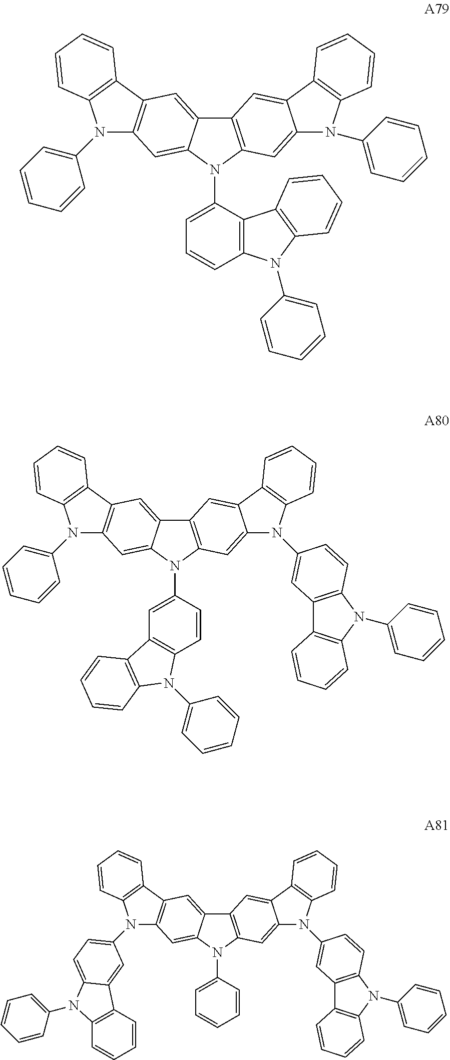

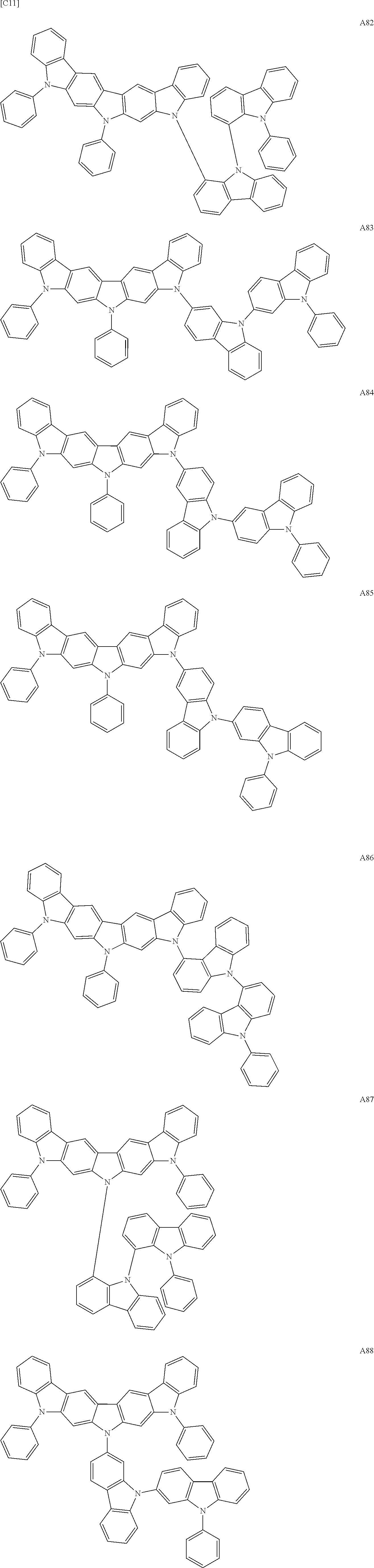

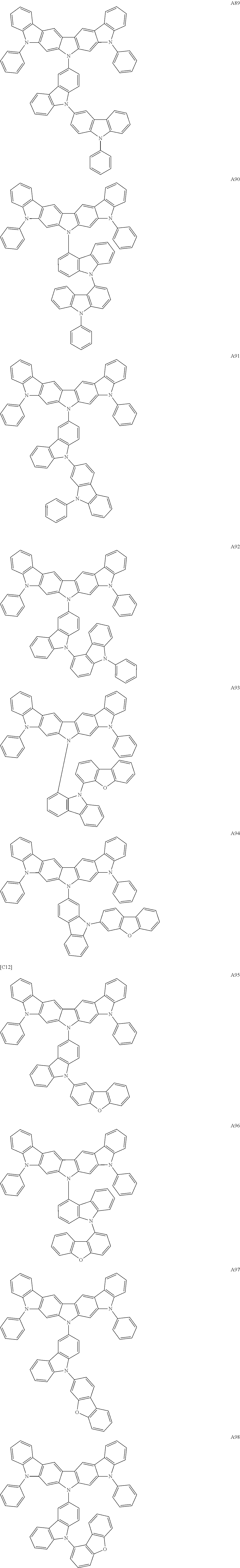

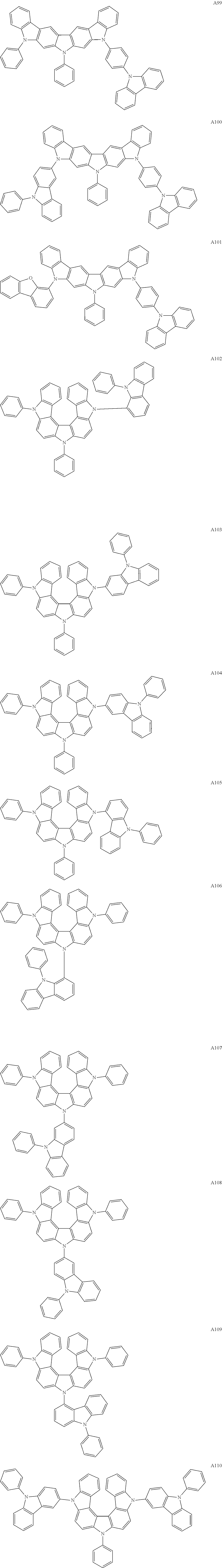

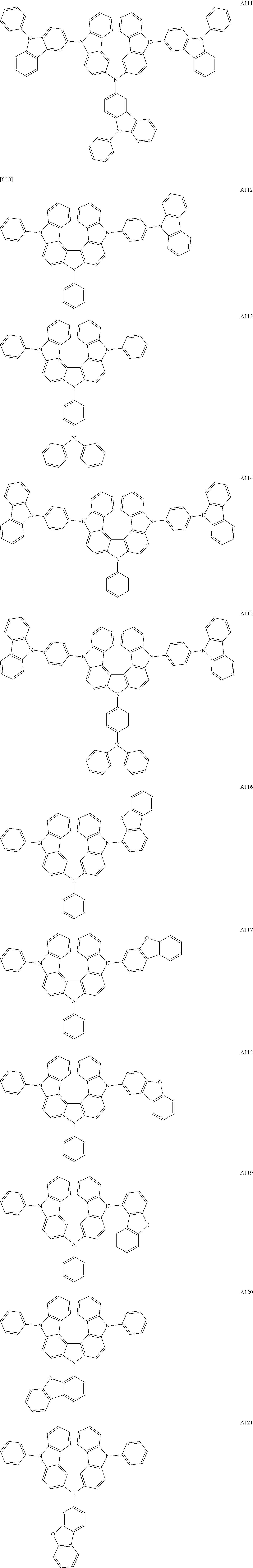

[chemical structure]

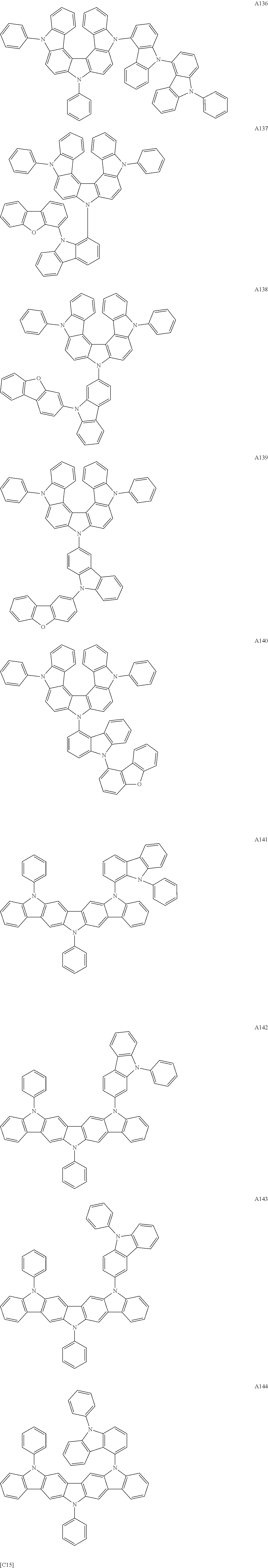

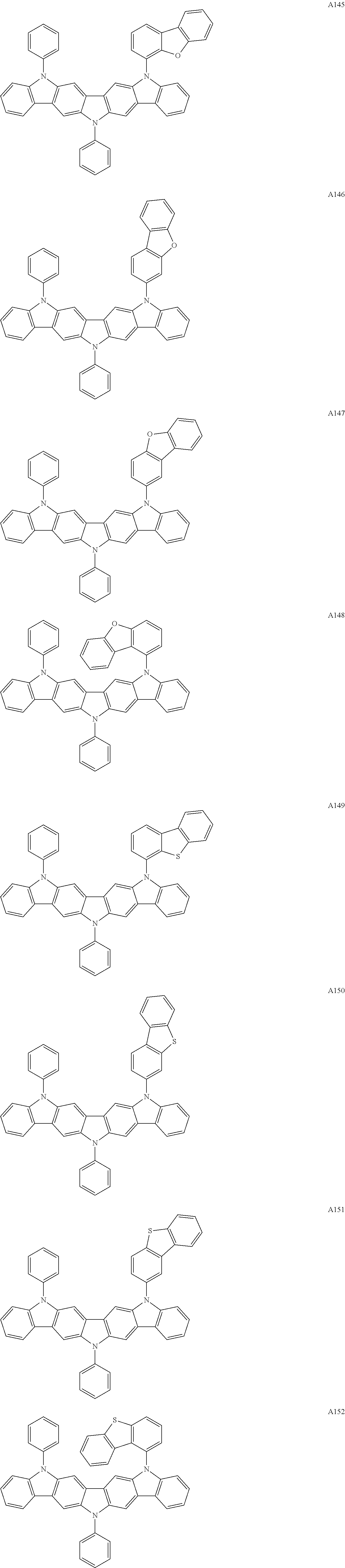

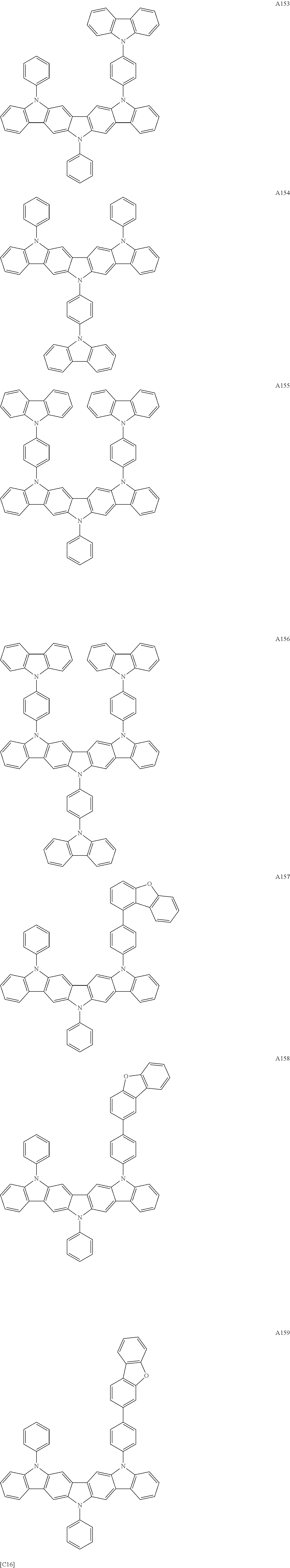

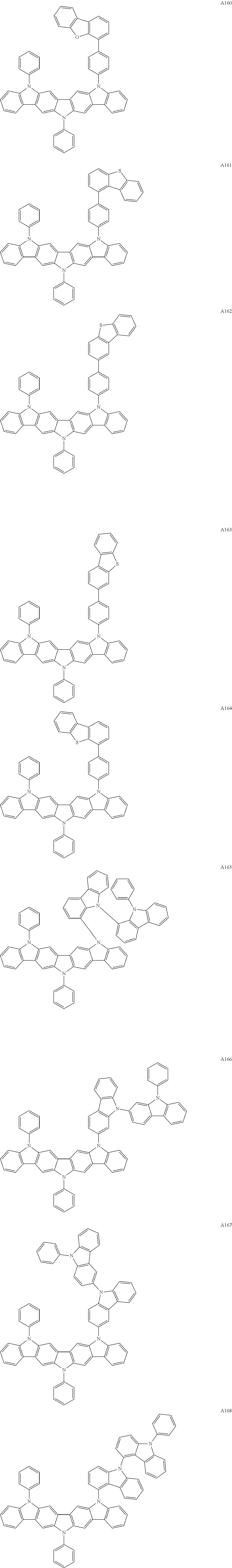

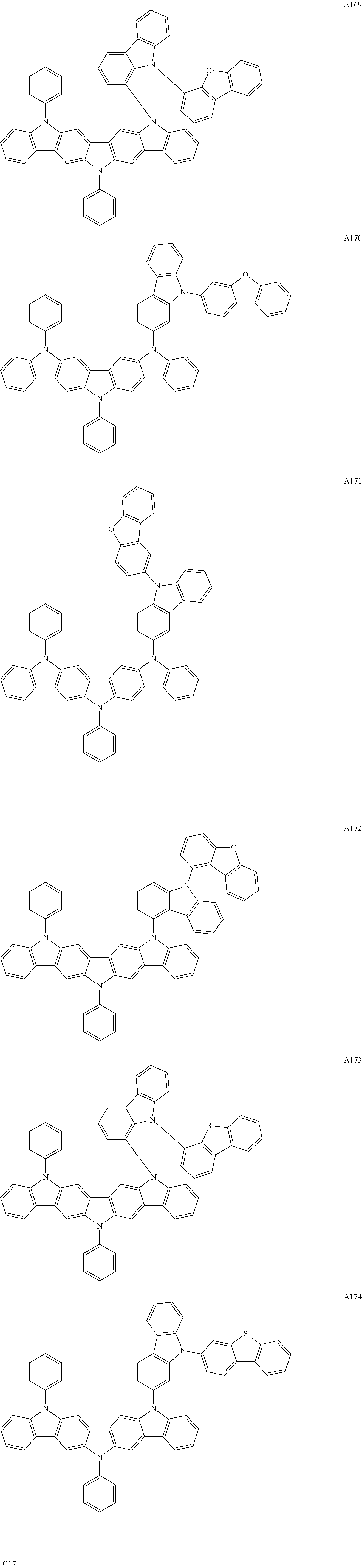

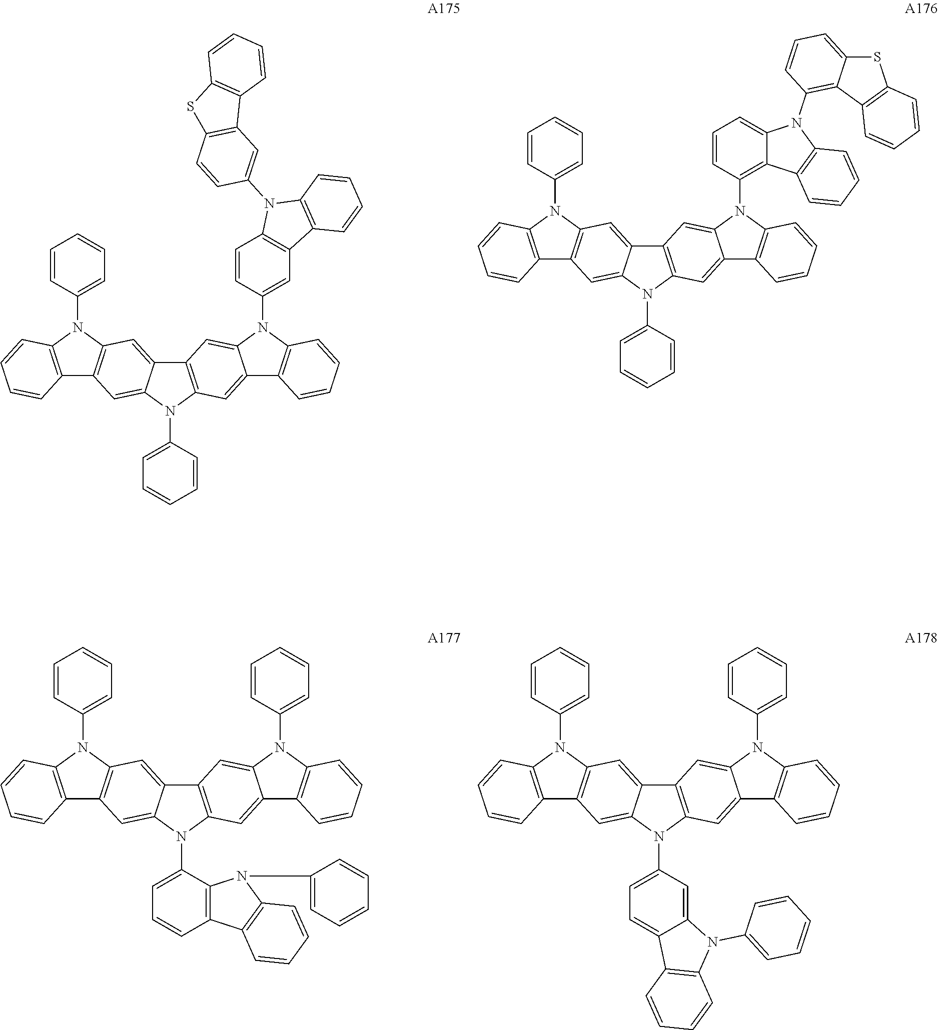

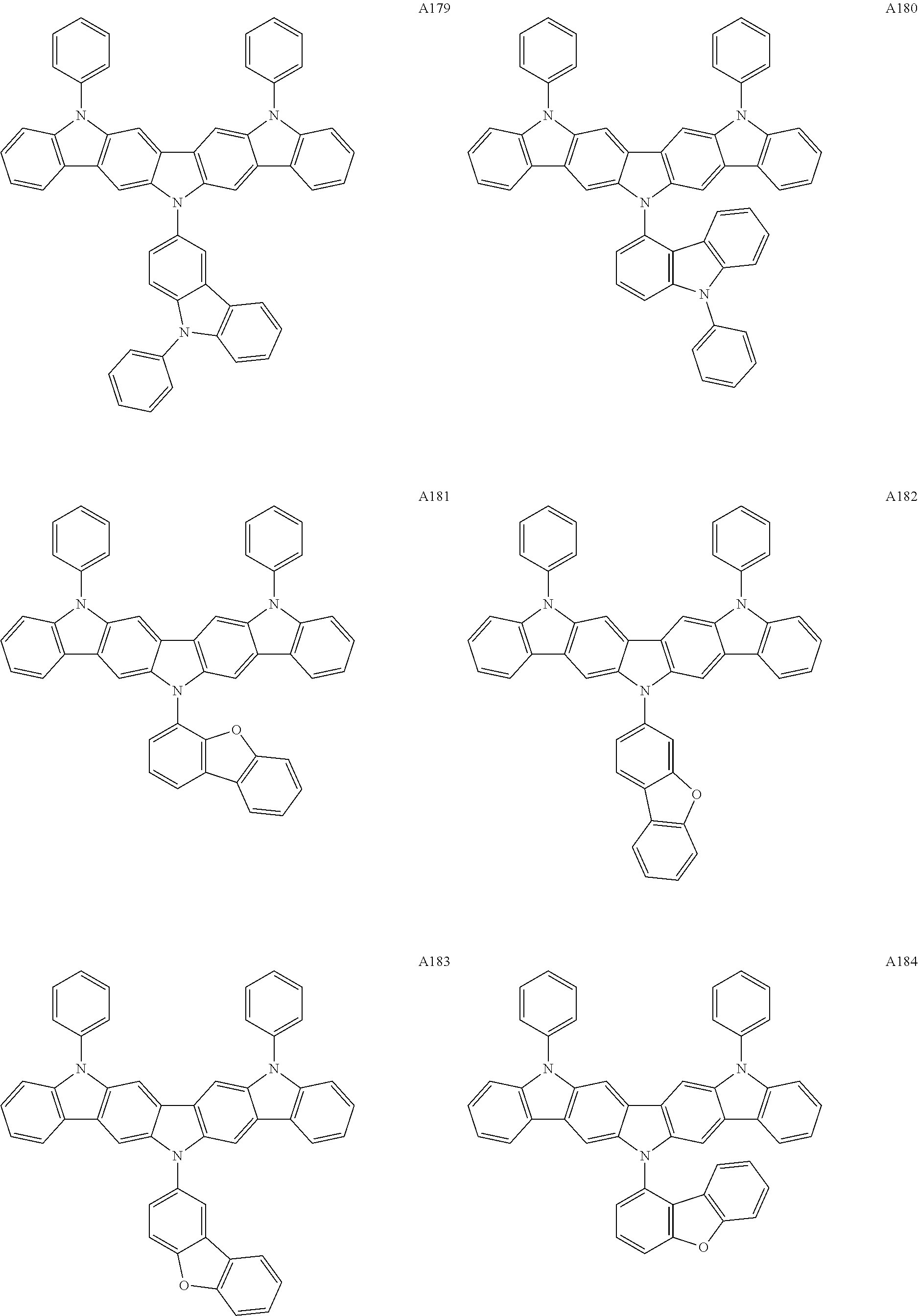

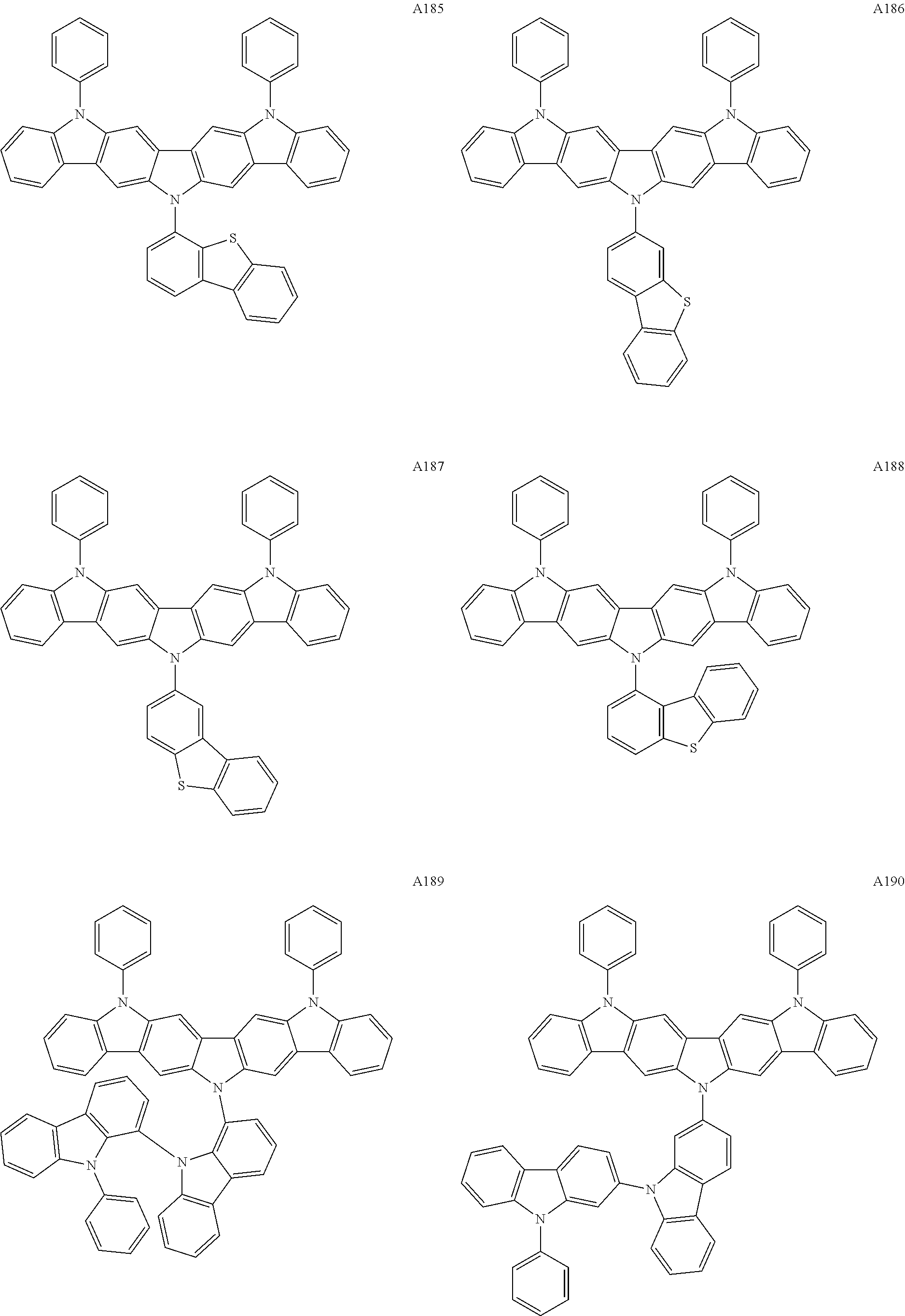

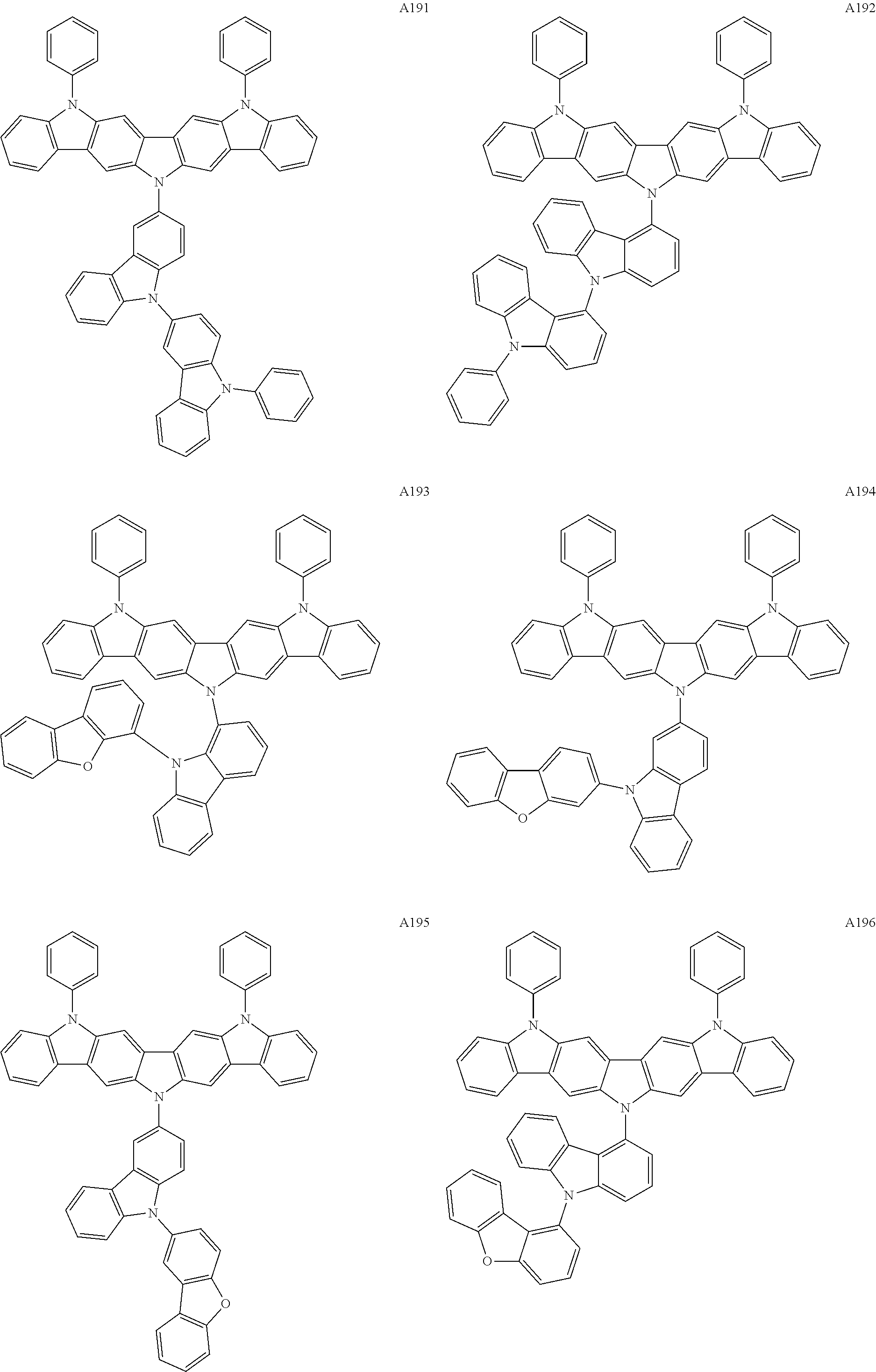

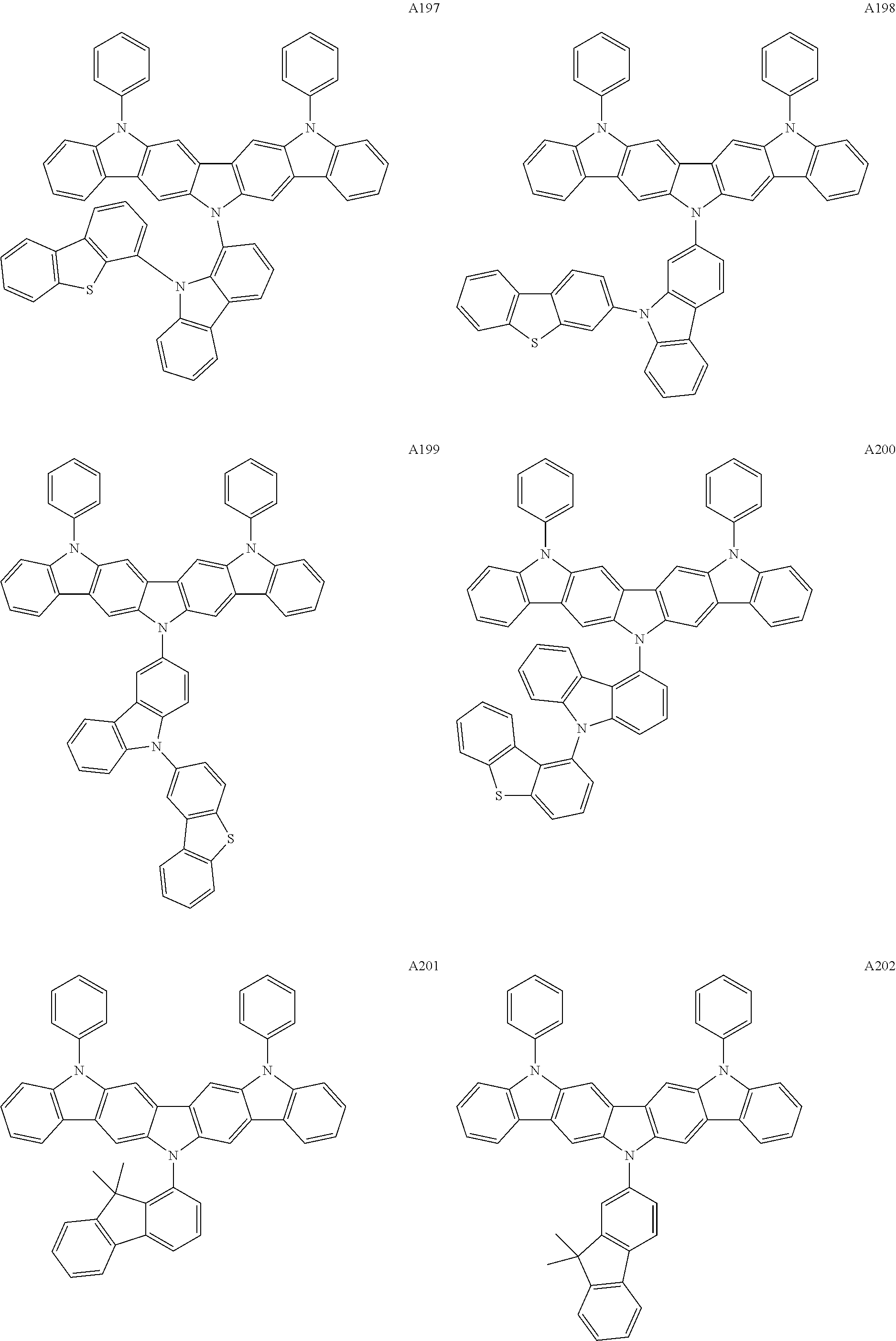

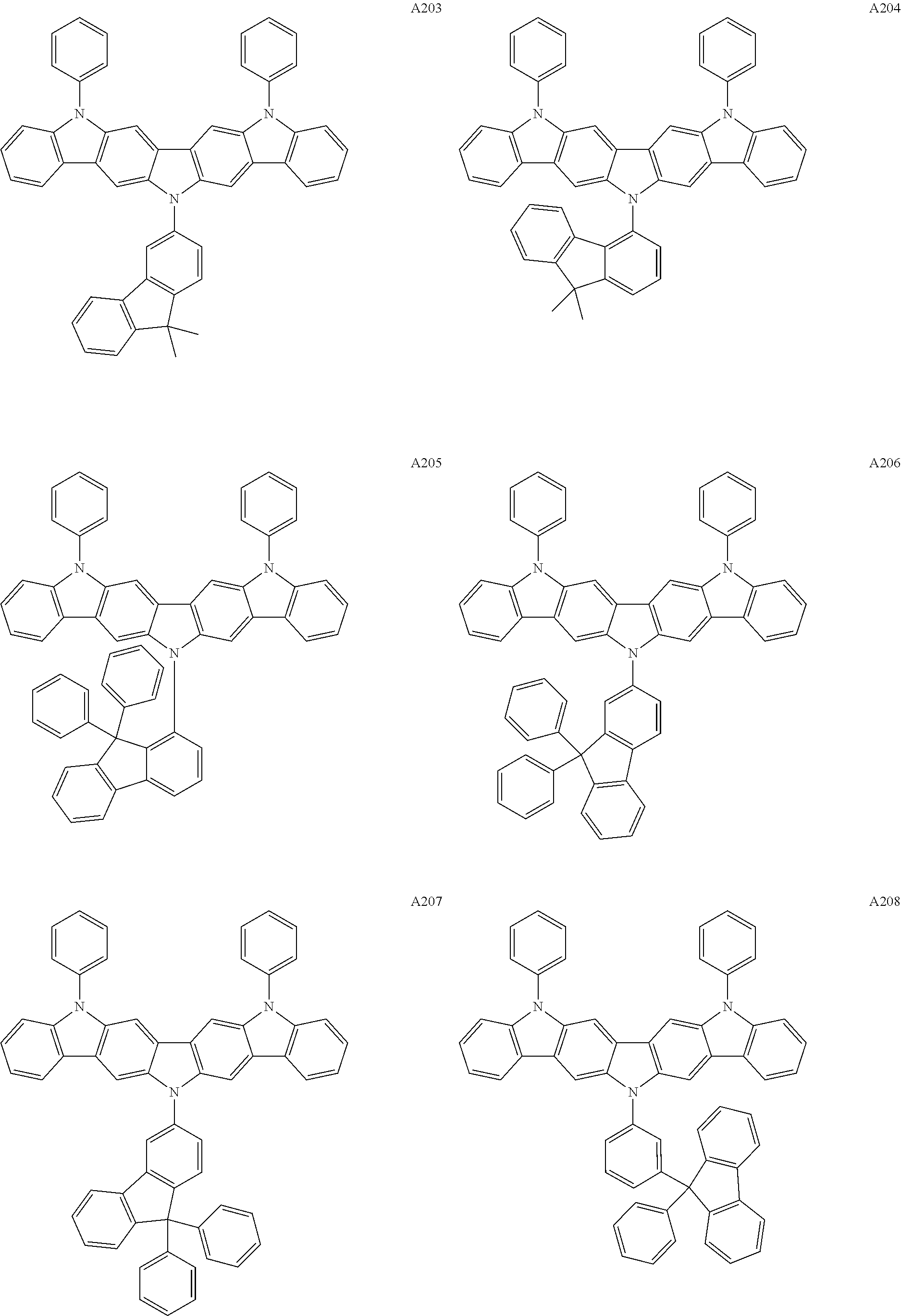

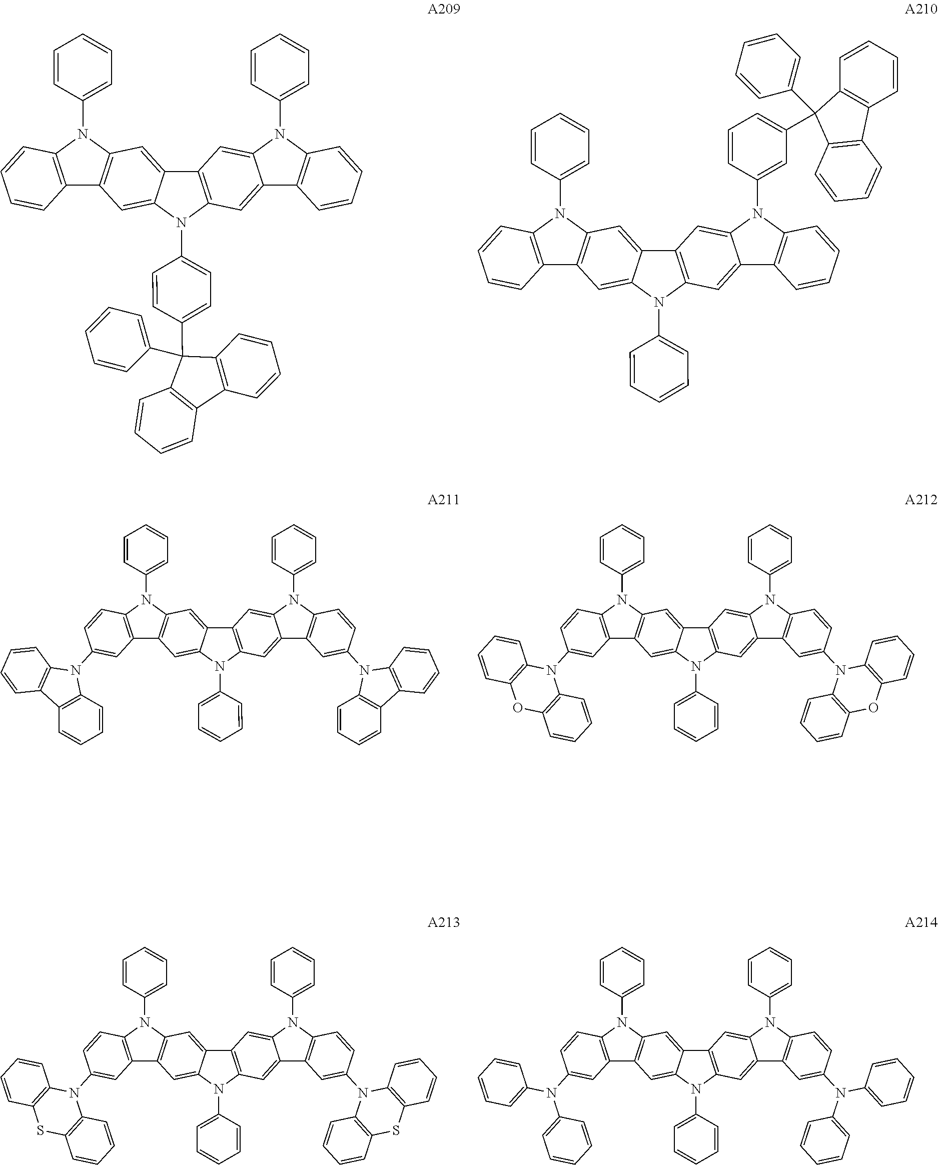

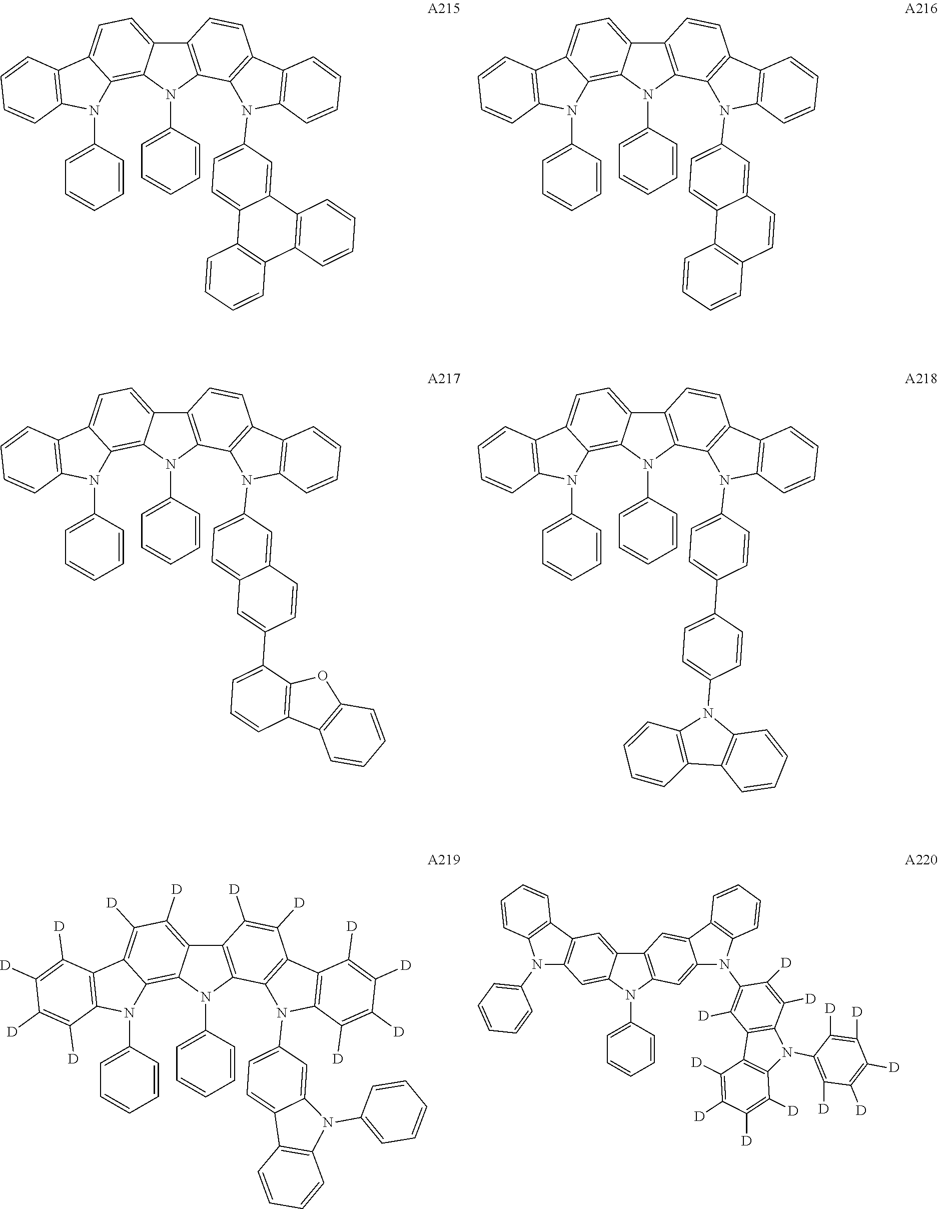

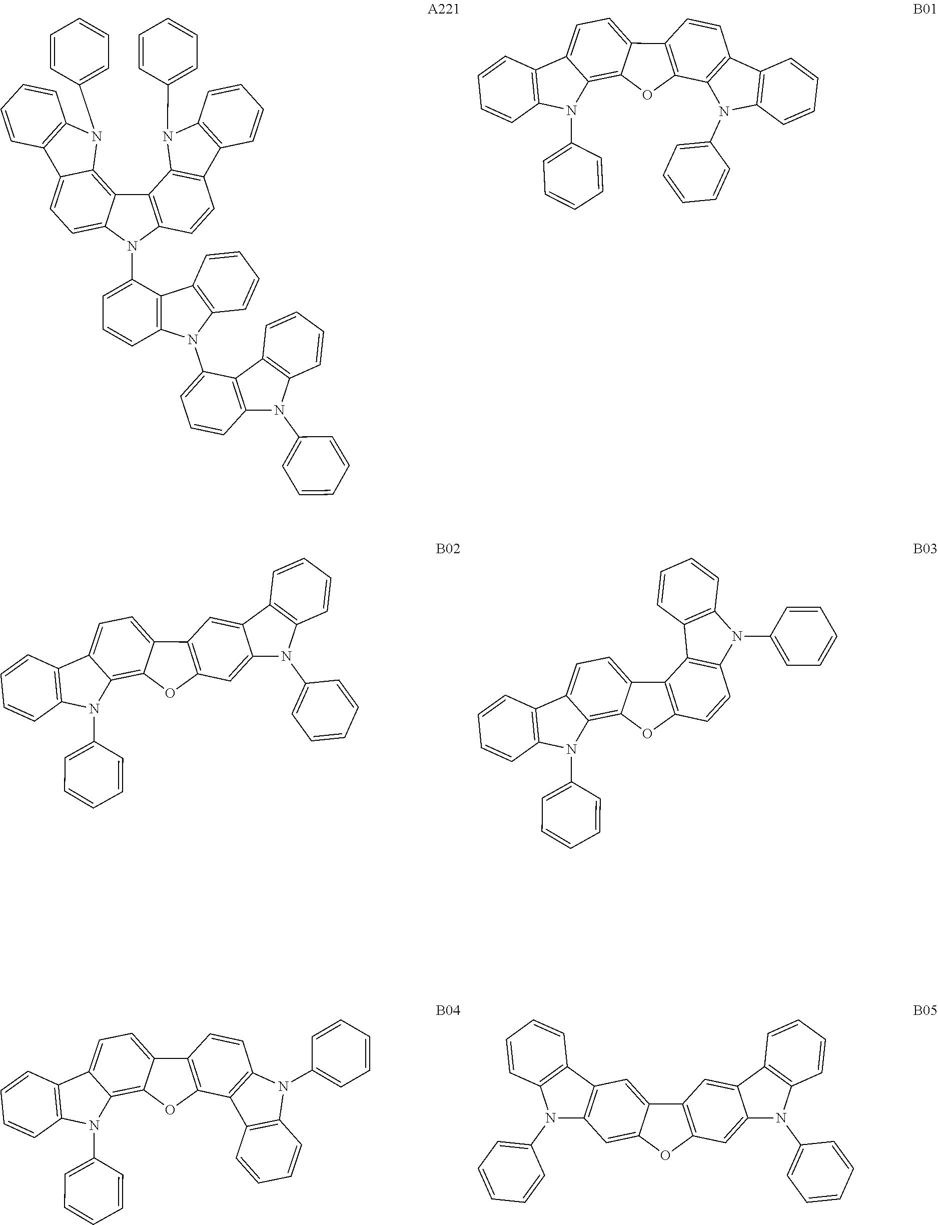

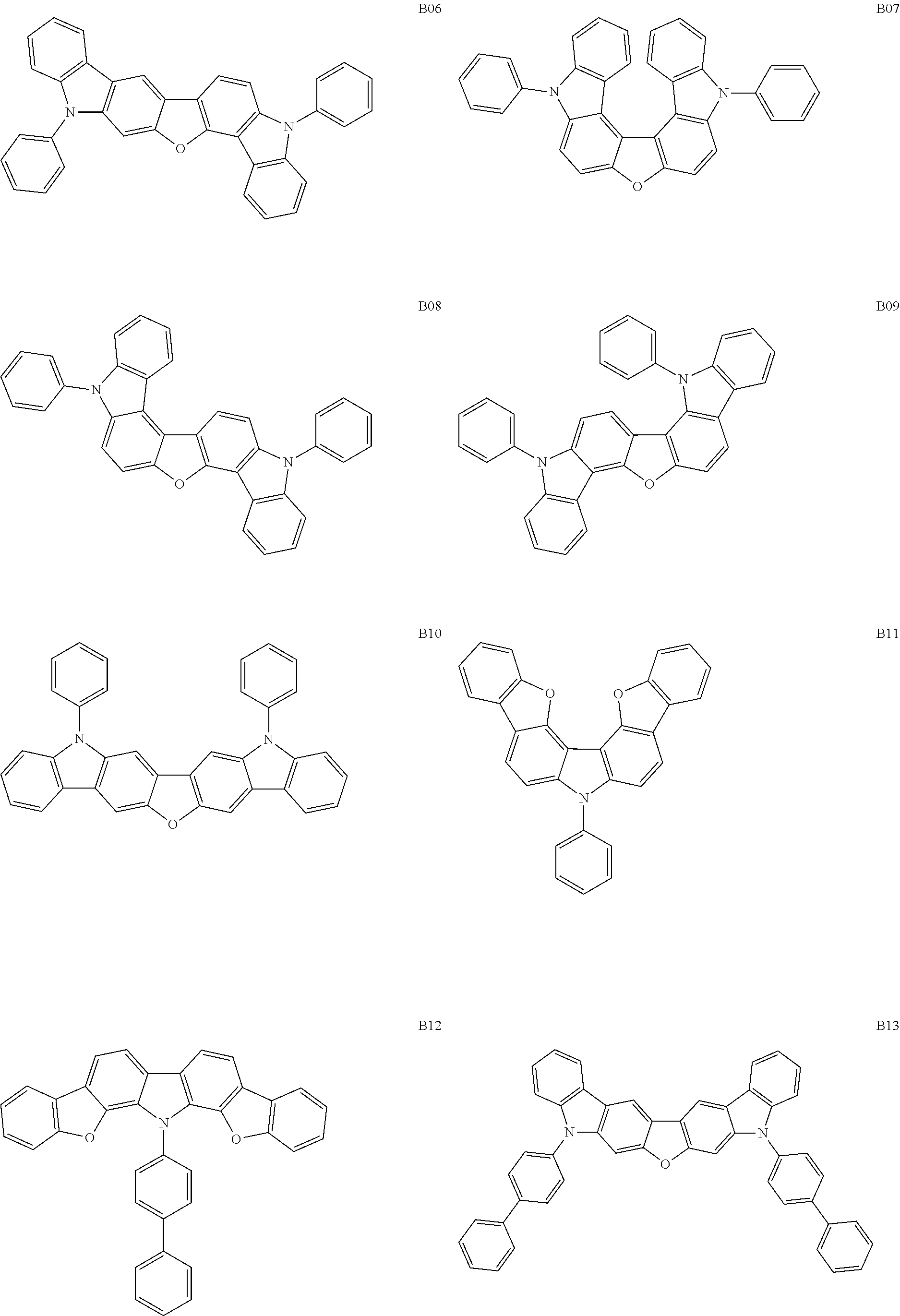

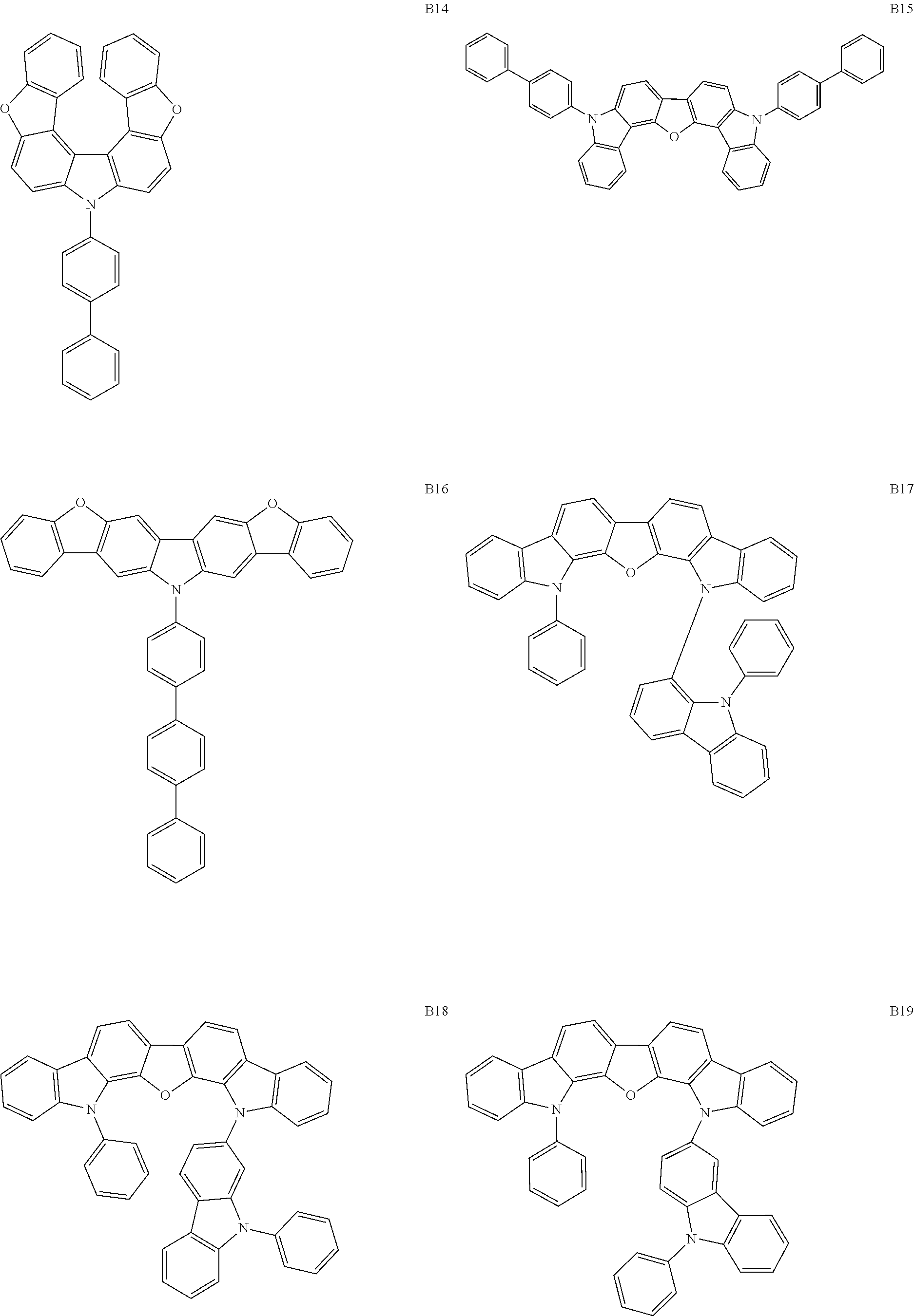

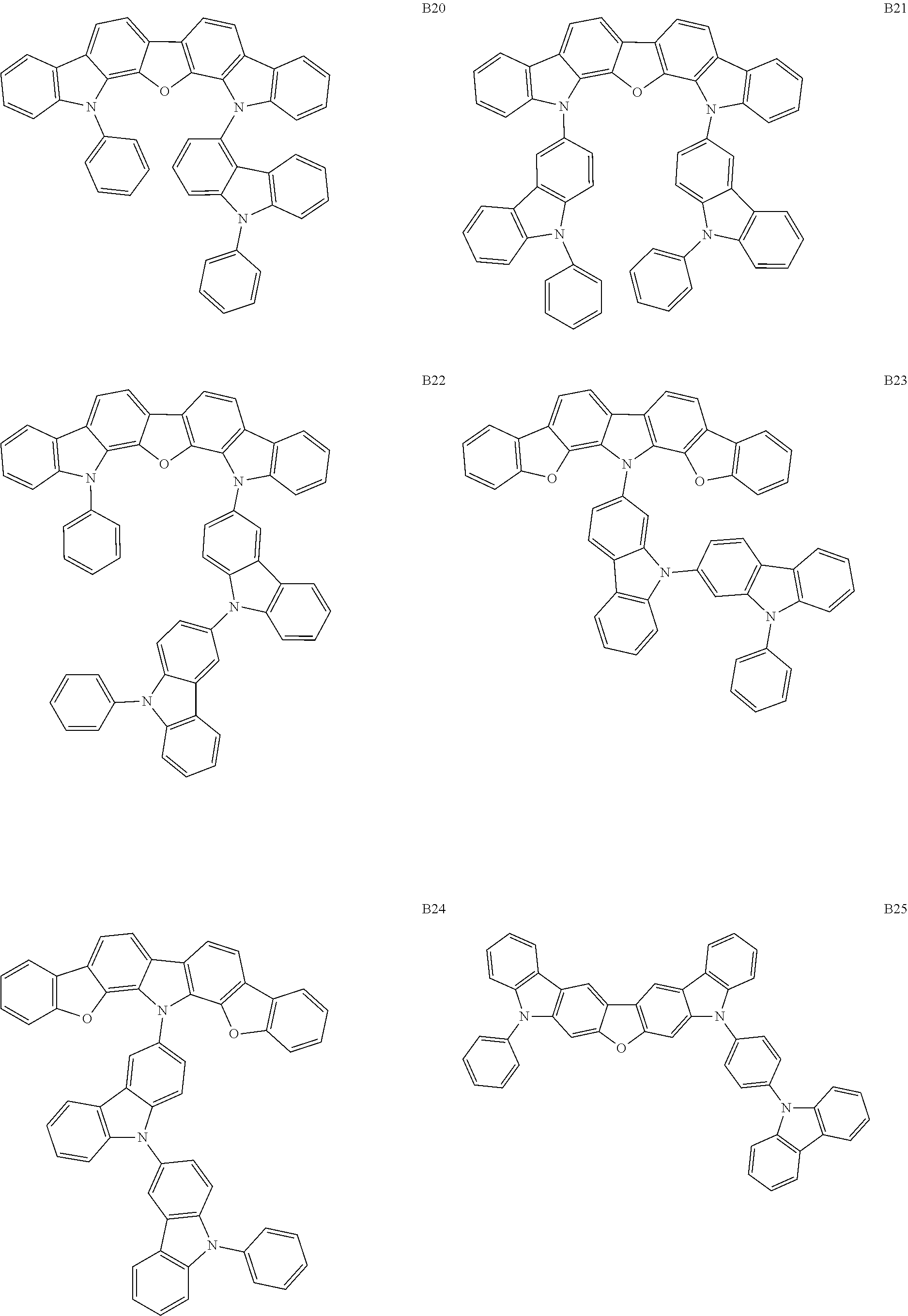

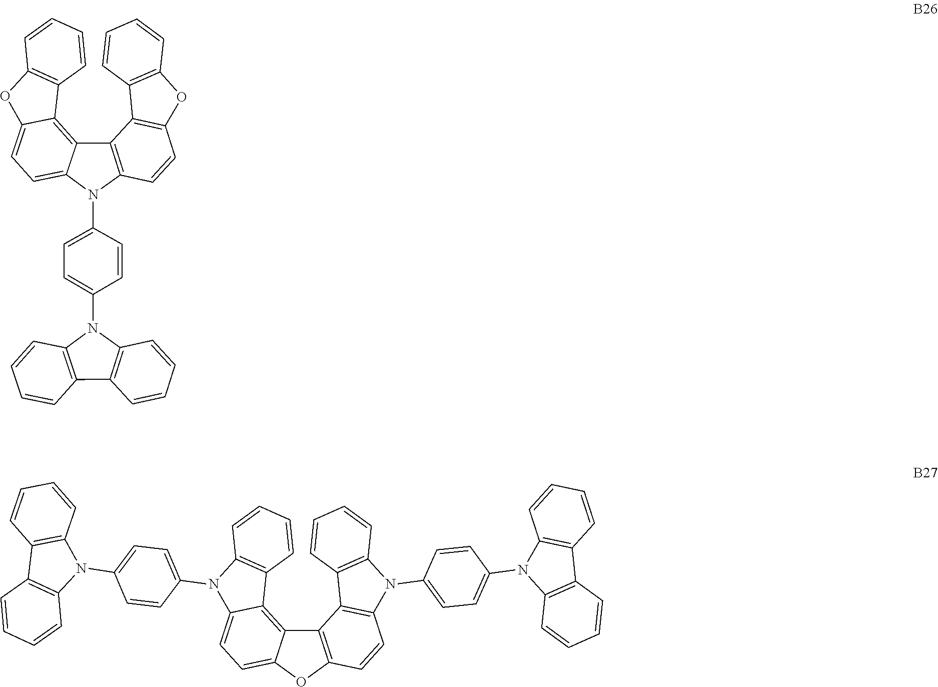

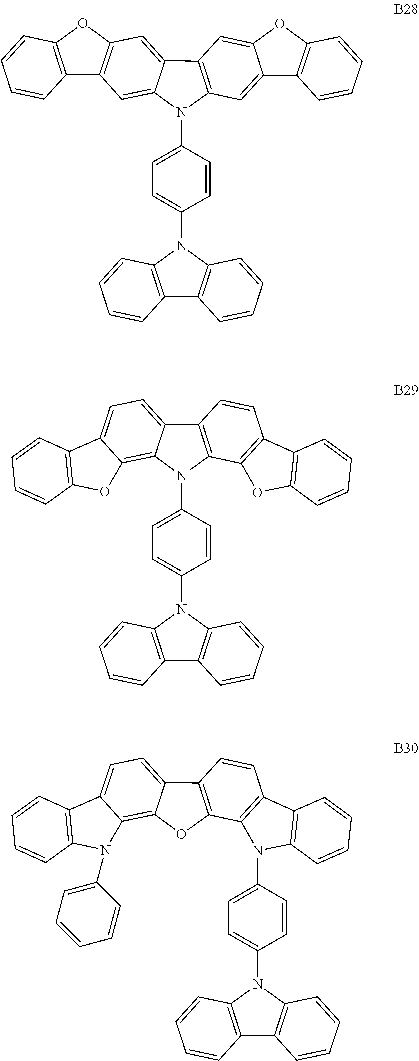

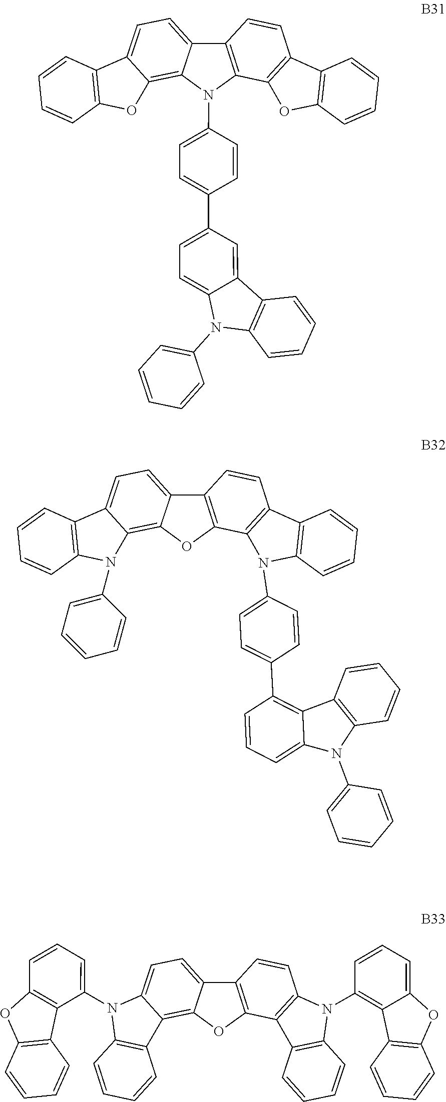

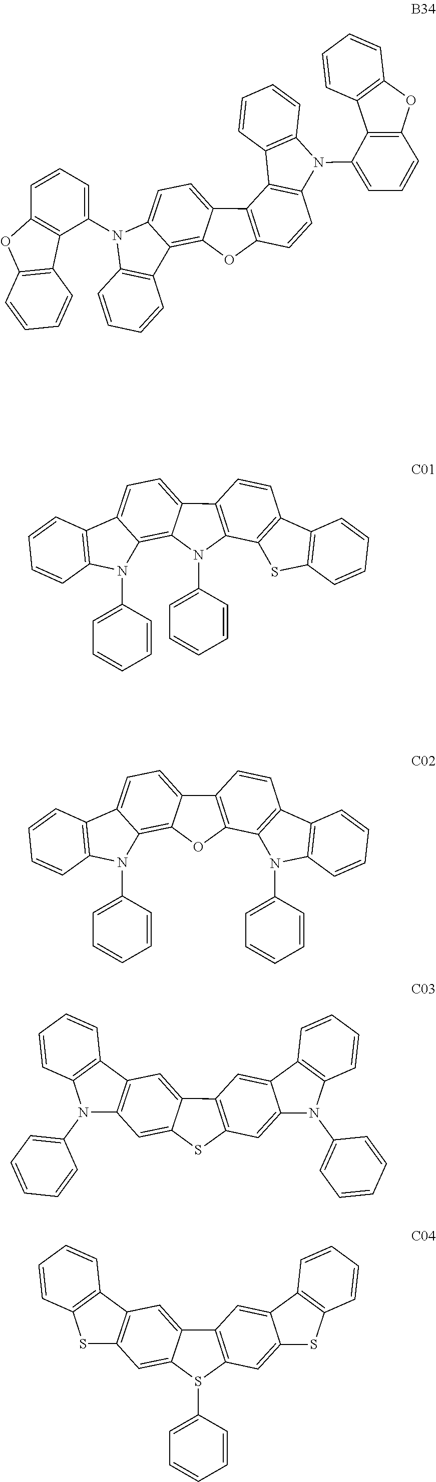

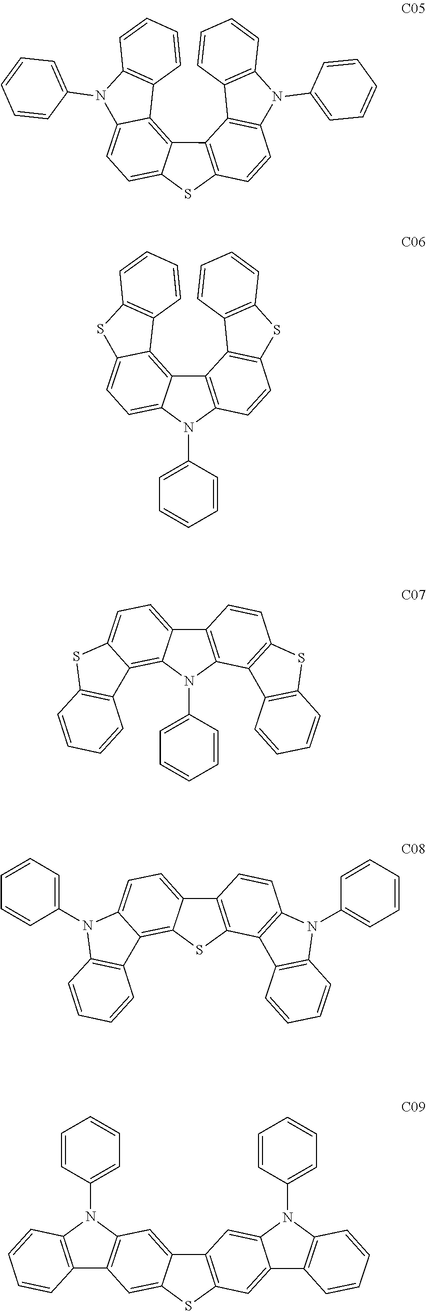

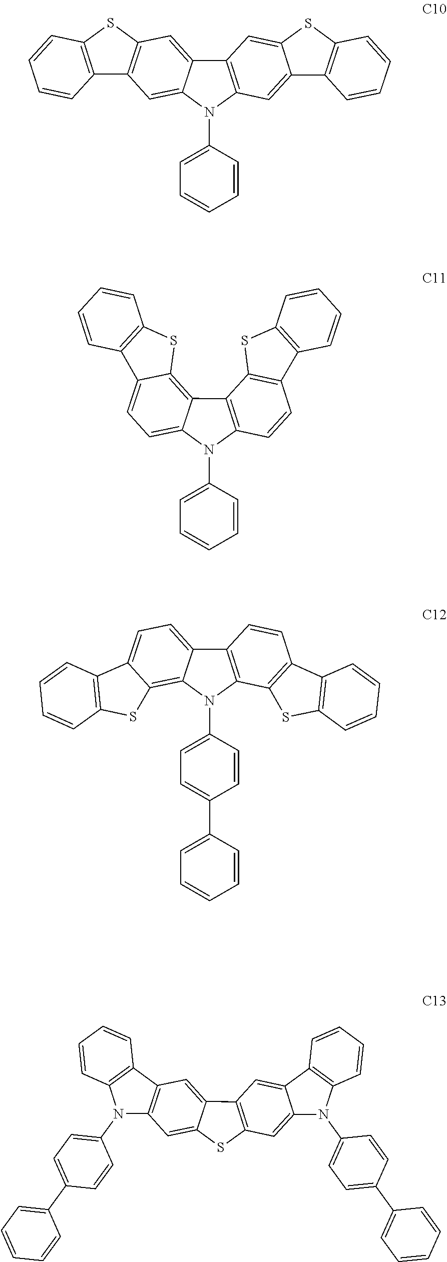

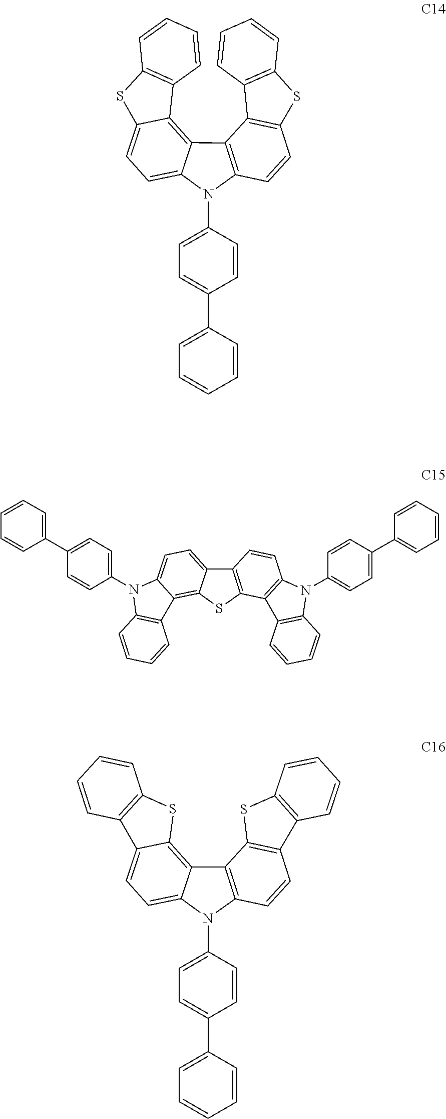

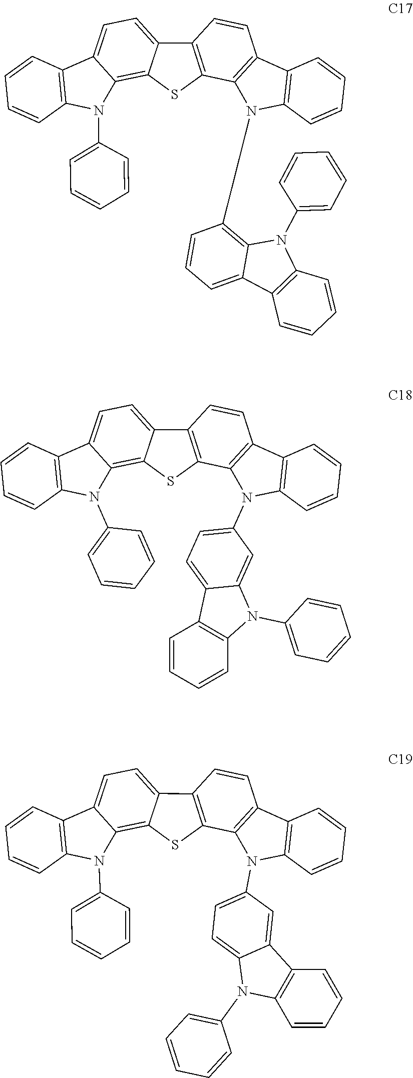

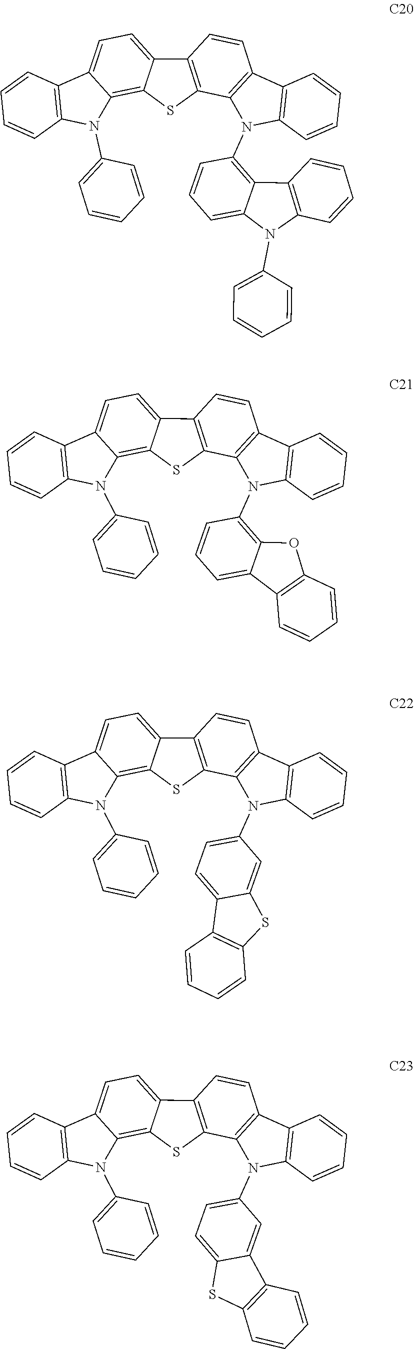

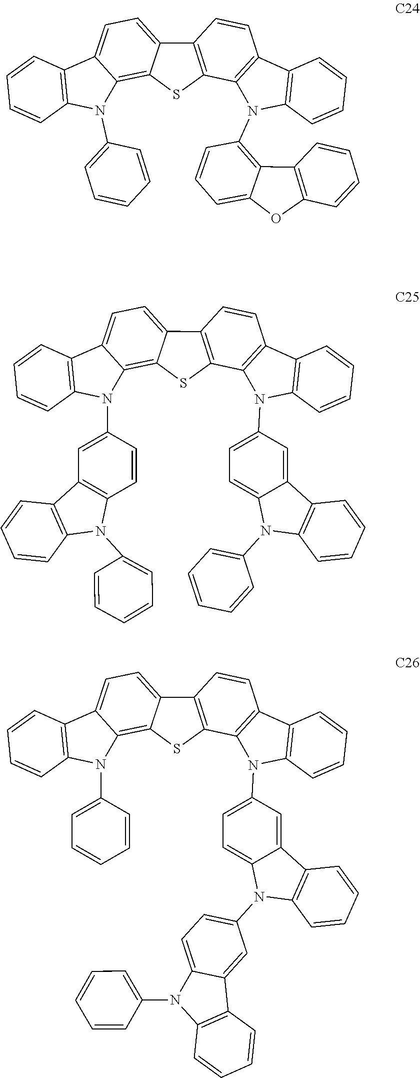

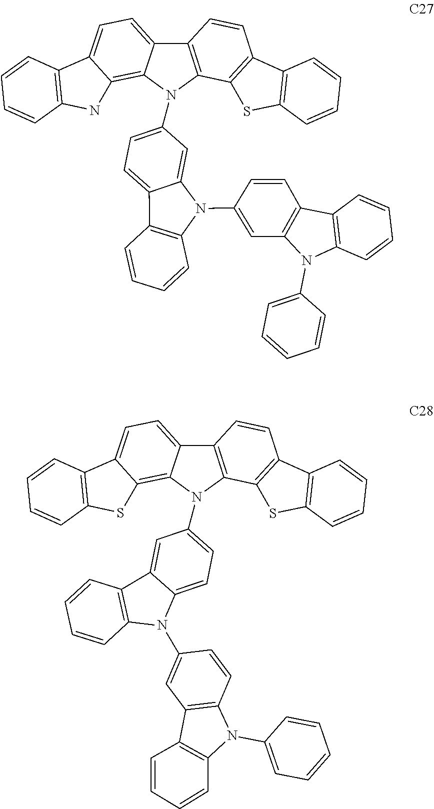

The compound of the present invention represented by the general formula (1) can be obtained by: synthesis by methods of various organic synthetic reactions established in the field of the organic synthetic chemistry including coupling reactions such as Suzuki coupling, Stille coupling, Grignard coupling, Ullmann coupling, Buchwald-Hartwig reaction, and Heck reaction, using commercially available reagents as raw materials; and then purification by using a known method such as recrystallization, column chromatography, and sublimation and purification. The method is not limited to this method.

The material for a photoelectric conversion device of the present invention preferably has an energy level of highest occupied molecular orbital (HOMO) obtained by structural optimization calculation with a density functional calculation B3LYP/6-31G(d) of −4.0 eV or lower, more preferably within a range of −6.0 eV to −4.5 eV, and further preferably within a range of −5.5 eV to −4.5 eV.

The material for a photoelectric conversion device of the present invention preferably has an energy level of lowest unoccupied molecular orbital (LUMO) obtained by structural optimization calculation with a density functional calculation B3LYP/6-31G(d) of −2.5 eV or higher, more preferably within a range of −2.5 eV to −0.5 eV, and further preferably within a range of −1.5 eV to −0.5 eV.

In the material for a photoelectric conversion device of the present invention, a difference (absolute value) between the HOMO energy level and the LUMO energy level is preferably within a range of 2.0 eV to 5.0 eV, more preferably within a range of 2.5 eV to 4.5 eV, and further preferably within a range of 3.0 eV to 4.5 eV.

The hole mobility of the material for a photoelectric conversion device of the present invention is preferably 1×10⁻⁶ cm²/Vs or more, and is preferably 1×10⁻⁶ cm²/Vs to 1 cm²/Vs, more preferably 1×10⁻⁵ cm²/Vs to 1×10⁻¹ cm²/Vs. The hole mobility can be evaluated by known methods such as a method with a FET-type transistor device, a method with a time-of-flight method, and an SCLC method.

The material for a photoelectric conversion device of the present invention is preferably amorphous. The amorphousness can be confirmed by various methods, and can be confirmed by, for example, detecting no peak in an XRD method or by detecting no endothermic peak in a DSC method.

Next, a photoelectric conversion device for imaging using the material for a photoelectric conversion device of the present invention will be described with reference to the drawing, but a structure of the photoelectric conversion device for imaging of the present invention is not limited thereto.

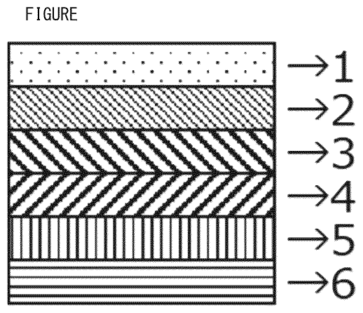

FIG. 1 is a sectional view schematically illustrating a structural example of the photoelectric conversion device for imaging of the present invention. In FIG. 1, 1 represents an electrode, 2 represents a hole blocking layer, 3 represents a photoelectric conversion layer, 4 represents an electron blocking layer, 5 represents an electrode, and 6 represents a substrate. Note that acceptable is structure in which configuration except for the substrate is inverted from that in FIG. 1, that is, 1 may represent the electrode, 2 may represent the electron blocking layer, 3 may represent the photoelectric conversion layer, 4 may represent the hole blocking layer, 5 may represent the electrode, and 6 may represent the substrate. The structure is not limited to one in FIG. 1, and a layer may be added or omitted as necessary.

### —Electrode—

An electrode used for the photoelectric conversion device for imaging using the material for a photoelectric conversion device for imaging of the present invention has a function of trapping a hole and an electron generated in the photoelectric conversion layer. A function to let light enter the photoelectric conversion layer is also required. Thus, at least one of two electrodes is desirably transparent or semi-transparent. A material used for the electrode is not particularly limited as long as it has conductivity, and examples thereof include: conductive transparent materials, such as ITO, IZO, SnO₂, ATO (antimony-doped tin oxide), ZnO, AZO (Al-doped zinc oxide), GZO (gallium-doped zinc oxide), TiO₂, and FTO; metals, such as gold, silver, platinum, chromium, aluminum, iron, cobalt, nickel, and tungsten; inorganic conductive substances, such as copper iodide and copper sulfide; and conductive polymers, such as polythiophene, polypyrrole, and polyaniline. A plurality of these materials may be mixed to use as necessary. In addition, two or more layers thereof may be stacked.

### —Photoelectric Conversion Layer—

The photoelectric conversion layer is a layer in which a hole and an electrode are generated by charge separation of an exciton generated by the incident light. The photoelectric conversion layer may be formed with a single photoelectric converting material, or may be formed by combination with a P-type organic semiconductor material being a hole transport material and an N-type organic semiconductor material being an electron transport material. Two or more kinds of the P-type organic semiconductor may be used, and two or more kinds of the N-type organic semiconductor may be used. One or more kinds of these P-type organic semiconductor and/or N-type semiconductor desirably use a dye material having a function of absorbing light with a desired wavelength in the visible region. As the P-type organic semiconductor material being the hole transport material, the compound of the present invention represented by the general formula (1) can be used.

The P-type organic semiconductor material may be any material having a hole transportability. The material represented by the general formula (1) is preferably used, but another P-type organic semiconductor material may be used. In addition, two or more kinds of the material represented by the general formula (1) may be mixed to use. Furthermore, the compound represented by the general formula (1) and another P-type organic semiconductor material may be mixed to use.

The another P-type organic semiconductor material may be any material having the hole transportability, and for example, usable are: compounds having a fused polycyclic aromatic group such as naphthalene, anthracene, phenanthrene, pyrene, chrysene, naphthacene, triphenylene, perylene, fluoranthene, fluorene, and indene; compounds having a m-excess aromatic group such as a cyclopentadiene derivative, a furan derivative, a thiophene derivative, a pyrrole derivative, a benzofuran derivative, a dibenzothiophene derivative, a dinaphthothienothiophene derivative, an indole derivative, a pyrazoline derivative, a dibenzofuran derivative, a dibenzothiophene derivative, a carbazole derivative, and an indolocarbazole; an aromatic amine derivative, a styrylamine derivative, a benzidine derivative, a porphyrin derivative, a phthalocyanine derivative, and a quinacridone derivative.

In addition, examples of a polymer P-type organic semiconductor material include a polyphenylene-vinylene derivative, a polyparaphenylene derivative, a polyfluorene derivative, a polyvinylcarbazole derivative, and a polythiophene derivative. Two or more kinds selected from the compound represented by the general formula (1), the P-type organic semiconductor material, and the polymer P-type organic semiconductor material may be mixed to use.

The N-type organic semiconductor material may be any material having the electron transportability, and examples thereof include naphthalenetetracarboxylic diimide and perylenetetracarboxylic diimide, fullerenes, and azole derivatives such as imidazole, thiazole, thiadiazole, oxazole, oxadiazole, and triazole. Two or more kinds selected from the N-type organic semiconductor materials may be mixed to use.

### —Electron Blocking Layer—

The electron blocking layer is provided in order to inhibit a dark current generated by injecting an electron from one electrode into the photoelectric conversion layer when a bias voltage is applied between the two electrodes. The electron blocking layer also has a function of hole transportation for transporting a hole generated by charge separation in the photoelectric conversion layer toward the electrode. A single layer or multiple layers of the electron blocking layer can be disposed as necessary. For the electron blocking layer, a P-type organic semiconductor material being the hole transport material can be used. The P-type organic semiconductor material may be any material having the hole transportability. Although the compound represented by the general formula (1) is preferably used, another P-type organic semiconductor material may be used. The compound represented by the general formula (1) and another P-type organic semiconductor material may be mixed to use. The other P-type organic semiconductor material may be any material having the hole transportability, and for example, usable are: compounds having a fused polycyclic aromatic group such as naphthalene, anthracene, phenanthrene, pyrene, chrysene, naphthacene, triphenylene, perylene, fluoranthene, fluorene, and indene; compounds having a t-excess aromatic group such as a cyclopentadiene derivative, a furan derivative, a thiophene derivative, a pyrrole derivative, a benzofuran derivative, a dibenzothiophene derivative, a dinaphthothienothiophene derivative, an indole derivative, a pyrazoline derivative, a dibenzofuran derivative, a dibenzothiophene derivative, and a carbazole derivative; an aromatic amine derivative, a styrylamine derivative, a benzidine derivative, a porphyrin derivative, a phthalocyanine derivative, and a quinacridone derivative.

In addition, examples of a polymer P-type organic semiconductor material include a polyphenylene-vinylene derivative, a polyparaphenylene derivative, a polyfluorene derivative, a polyvinylcarbazole derivative, and a polythiophene derivative. Two or more kinds selected from the compound of the present invention represented by the general formula (1), the P-type organic semiconductor material, and the polymer P-type organic semiconductor material may be mixed to use.

### —Hole Blocking Layer—

The hole blocking layer is provided in order to inhibit a dark current generated by injecting a hole from one electrode into the photoelectric conversion layer when a bias voltage is applied between the two electrodes. The hole blocking layer also has a function of electron transportation for transporting an electron generated by charge separation in the photoelectric conversion layer toward the electrode. A single layer or multiple layers of the hole blocking layer can be disposed as necessary. For the hole blocking layer, the N-type organic semiconductor material having the electron transportability can be used.

The N-type organic semiconductor material may be any material having the electron transportability, and examples thereof include: polycyclic aromatic multivalent carboxylic anhydride or imidized products thereof, such as naphthalenetetracarboxylic diimide and perylenetetracarboxylic diimide; fullerenes, such as C60 and C70; azole derivatives, such as imidazole, thiazole, thiadiazole, oxazole, oxadiazole, and triazole; a tris(8-quinolinolate) aluminum (III) derivative, a phosphine oxide derivative, a nitro-substituted fluorene derivative, a diphenylquinone derivative, a thiopyran dioxide derivative, a carbodiimide, a fluorenylidene methane derivative, an anthraquinodimethane derivative and an anthrone derivative, a bipyridine derivative, a quinoline derivative, and an indolocarbazole derivative. Two or more kinds of these N-type organic semiconductor materials may be mixed to use.

Hydrogen in the compound represented by the general formula (1) of the present invention may be deuterium. That is, a part or all of hydrogens on the aromatic rings in the general formulae (1) to (3) or the general formulae (4) to (24), and hydrogen of the substituents such as Art to Ar¹⁰ may be deuterium.

Furthermore, a part or all of hydrogens in a compound used as the N-type organic semiconductor material and the P-type organic semiconductor material may be deuterium.

A method for producing a film of each layer in producing the photoelectric conversion device for imaging of the present invention is not particularly limited. The photoelectric conversion device may be produced by any one of dry process and wet process.

The organic layer containing the material for a photoelectric conversion device of the present invention may be a plurality of the layers as necessary.

### EXAMPLES

Hereinafter, the present invention will be described in more detail with Examples, but the present invention is not limited to these Examples.

### Calculation Example

### Calculation of HOMO and LUMO

Calculated were HOMO, LUMO and a difference in energy of HOMO and LUMO of the above compounds A23, A26, A44, A61, A73, A86, A134, A196, A221, B24, B25, B33, B34, and C19. The calculation was performed by using a density functional theory (DFT), using Gaussian as a calculation program, and with structural optimization calculation of a density functional calculation B3LYP/6-31G(d). Table 1 shows the results. It can be mentioned that any of the materials for the photoelectric conversion device for imaging of the present invention has preferable HOMO and LUMO values.

Also, as comparative compounds, for the following compounds H1, H2, H3, and H4, HOMO, LUMO, and the difference in energy of HOMO and LUMO were calculated in the same manner. Table 1 shows the results.

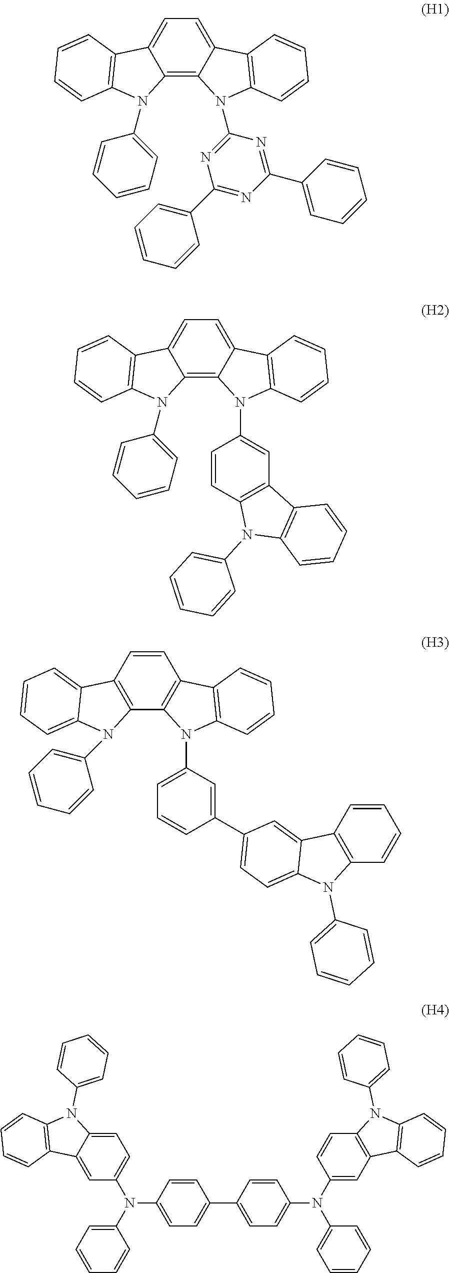

TABLE 1

| | HOMO | LUMO | Energy difference |
|---|---|---|---|
| Compound | [eV] | [eV] | [eV] |
| A23 | −4.8 | −1.0 | 3.8 |
| A26 | −4.6 | −1.2 | 3.4 |
| A44 | −5.0 | −1.1 | 3.9 |
| A61 | −4.8 | −1.0 | 3.8 |
| A73 | −4.8 | −0.9 | 3.9 |
| A86 | −4.7 | −1.1 | 3.7 |
| A134 | −4.5 | −1.0 | 3.6 |
| A196 | −4.6 | −1.2 | 3.4 |
| A221 | −4.8 | −1.1 | 3.7 |
| B24 | −5.1 | −1.0 | 4.0 |
| B25 | −5.0 | −1.0 | 4.0 |
| B33 | −5.0 | −1.2 | 3.8 |
| B34 | −5.1 | −1.2 | 3.8 |
| C19 | −5.0 | −1.1 | 4.0 |
| H1 | −5.3 | −1.9 | 3.4 |
| H2 | −5.0 | −0.9 | 4.1 |
| H3 | −5.1 | −0.8 | 4.2 |
| H4 | −4.5 | −0.8 | 3.7 |

A synthesis example of the compound A23 will be described below as a representative example. The other compounds were also synthesized by a similar method.

### Synthesis Example 1 (Synthesis of Intermediate R3)

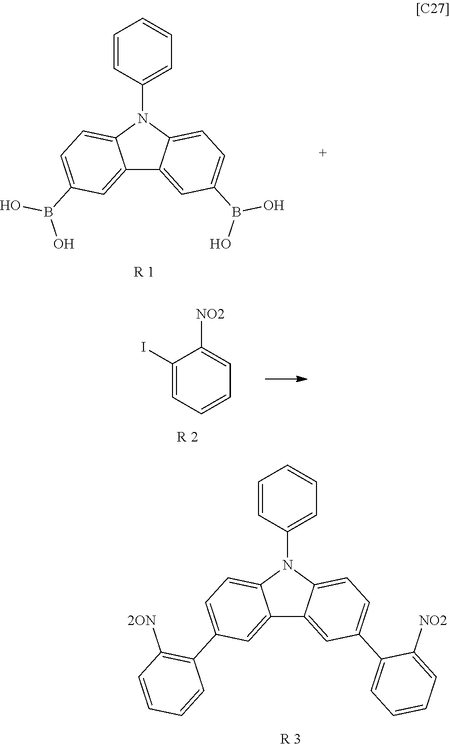

Into a three-necked 300-ml flask with degassed and nitrogen-replenished, R1 (30.2 mmol), R2 (66.5 mmol), tetrakistriphenylphosphine palladium (0.6 mmol), and potassium carbonate tripotassium phosphate (81.3 mmol) were added, 60 ml of toluene, 20 ml of ethanol, and 20 ml of water were added thereto, and then the mixture was stirred at 100° C. for 5 hours. The mixture was cooled to a room temperature, then 50 ml of toluene and 50 ml of water were added thereto and transferred to a separatory funnel, and separation into an organic layer and an aqueous layer was performed. The organic layer was washed three times with 100 ml of water, and then the obtained organic layer was dehydrated with magnesium sulfate, and then concentrated under a reduced pressure. The obtained residue was purified by silica gel column chromatography to obtain 11.5 g of R3 (pale yellow solid).

### (Synthesis of Intermediate R4)

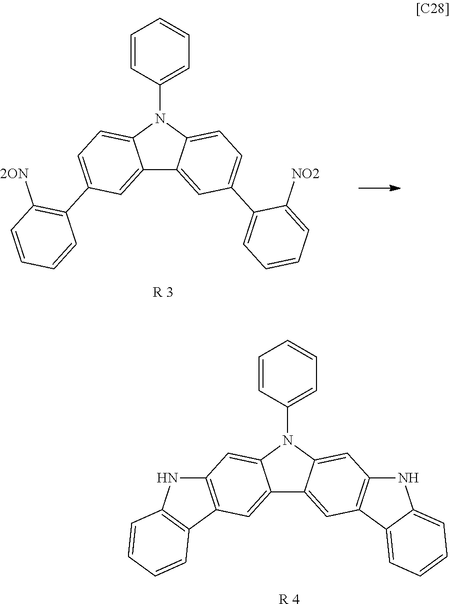

Into a three-necked 300-ml flask with degassed and nitrogen-replenished, R3 (20.6 mmol) and triphenylphosphine (82.4 mmol) were added, 100 ml of o-dichlorobenzene was added thereto, and then the mixture was stirred at 190° C. for 5 hours. The mixture was cooled to a room temperature, and then purified by silica gel column chromatography to obtain 4.3 g of R4 (pale yellow solid).

### (Synthesis of A23)

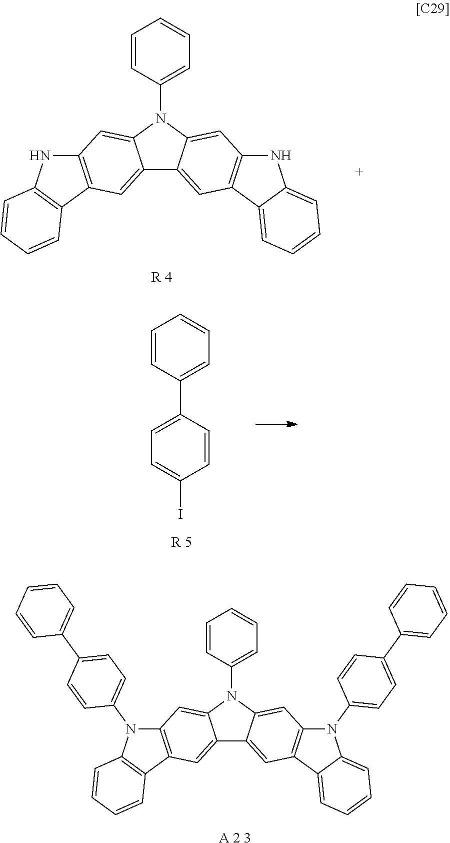

Into a three-necked 200-ml flask with degassed and nitrogen-replenished, R4 (9.5 mmol), R5 (28.5 mmol), copper iodide (2.8 mmol), and potassium carbonate (47.4 mmol) were added, 50 ml of DMI was added thereto, and then the mixture was stirred at 190° C. for 20 hours. The mixture was cooled to a room temperature, then an inorganic substance was removed by filtration, the filtrate was added to a 400 ml of a mixed solution of ethanol/water=1/1, and a solid precipitated was recovered by suction filtration. The obtained solid was purified by column chromatography to obtain 6.1 g of A23 (pale yellow solid). The yield rate was 89%. Mass analysis of the obtained solid was performed, and the mass number was 725. The obtained solid was evaluated by an XRD method but no peak was detected. Thus, this compound was found to be amorphous.

### Example of Physical Properties Evaluation

On a glass substrate on which a transparent electrode composed of ITO with 110 nm in film thickness was formed, the compound A23 was produced to a film as an organic layer by a vacuum deposition method under a condition that a film thickness was approximately 3 μm. Subsequently, charge mobility was measured by a time-of-flight method using a device in which aluminum (Al) was formed with 70 nm in thickness as an electrode. As a result, the hole mobility was 3.5×10⁻⁴ cm²/Vs.

The hole mobilities were evaluated in the same procedure as above except that A26, A44, A61, A73, A86, A134, A221, B25, B33, B34, H1, H2, H3, and H4 was used instead of the compound A23. Table 2 shows the results.

TABLE 2

| | Hole mobility |
|---|---|
| Compound | [cm²/Vs] |
| A23 | 3.5 × 10⁻⁴ |
| A26 | 1.5 × 10⁻³ |
| A44 | 1.2 × 10⁻⁴ |
| A61 | 2.6 × 10⁻⁴ |
| A73 | 4.1 × 10⁻⁴ |
| A86 | 9.5 × 10⁻⁵ |
| A134 | 1.9 × 10⁻⁴ |
| A221 | 9.2 × 10⁻⁵ |
| B25 | 2.3 × 10⁻⁴ |
| B33 | 3.5 × 10⁻⁵ |
| B34 | 6.9 × 10⁻⁵ |
| H1 | 4.0 × 10⁻⁵ |
| H2 | 3.0 × 10⁻⁵ |
| H3 | 1.0 × 10⁻⁴ |
| H4 | 6.5 × 10⁻⁴ |

### Example 1

On an electrode composed of ITO with 70 nm in film thickness formed on a glass substrate, a 10-nm film of the compound A23 was formed with a vacuum degree of 4.0×10⁻⁵ Pa as an electron blocking layer. Then, 2Ph-BTBT, F6-SubPc-OC6F5, and fullerene (C60) were co-deposited at a deposition rate ratio of 4:4:2 with a thickness of 200 nm to form a film as a photoelectric conversion layer. Subsequently, 10-nm of dpy-NDI was deposited to form a hole blocking layer. Finally, an aluminum film was formed with 70 nm in thickness as an electrode to produce a photoelectric conversion device.

A current in a dark place (dark current) was 3.6×10⁻¹⁰ A/cm² with the electrodes of ITO and aluminum and with applying a voltage of 2.6 V. When a voltage of 2.6 V was applied and the ITO electrode side was irradiated with light with an LED adjusted to be an irradiation light wavelength of 500 nm and 1.6 μW from a height of 10 cm, a current (bright current) was 3.2×10⁻⁷ A/cm². A contrast ratio was 8.9×10² with applying a voltage of 2.6 V.

### Examples 2 to 9

Photoelectric conversion devices were produced in the same manner as in Example 2 except that compounds shown in Table 3 were used as the electron blocking layer.

### Comparative Examples 1 to 4

Photoelectric conversion devices were produced in the same manner as in Example 2 except that compounds shown in Table 3 were used as the electron blocking layer.

Table 3 shows the results of Examples 1 to 9 and Comparative Examples 1 to 4.

Table 4 shows the calculation results of HOMO and LUMO of each compound used in Examples and Comparative Examples, other than the compounds shown in Table 1 above. The calculation was performed by using a density functional theory (DFT) as in the above case, using Gaussian as a calculation program, and with structural optimization calculation of a density functional calculation B3LYP/6-31G(d).

### [C30]

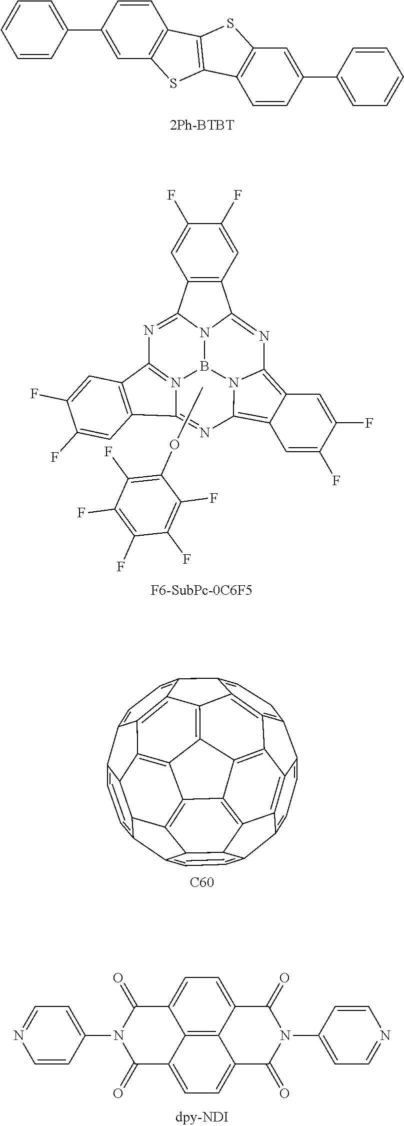

TABLE 3

| | | | | | Difference |
|---|---|---|---|---|---|
| | | Dark | Bright | | in energy |
| | Com- | current | current | Contrast | level \| h1 − |
| | pound | [A/cm²] | [A/cm²] | ratio | e1 \| [eV] |
| Example 1 | A23 | 3.6 × 10⁻¹⁰ | 3.2 × 10⁻⁷ | 8.9 × 10² | 0.6 |
| Example 2 | A61 | 3.4 × 10⁻¹⁰ | 3.3 × 10⁻⁷ | 9.7 × 10² | 0.6 |
| Example 3 | A73 | 4.1 × 10⁻¹⁰ | 3.2 × 10⁻⁷ | 7.8 × 10² | 0.6 |
| Example 4 | A86 | 2.9 × 10⁻¹⁰ | 3.0 × 10⁻⁷ | 1.0 × 10³ | 0.7 |
| Example 5 | A134 | 3.0 × 10⁻¹⁰ | 3.4 × 10⁻⁷ | 1.1 × 10³ | 0.9 |
| Example 6 | A221 | 3.2 × 10⁻¹⁰ | 3.1 × 10⁻⁷ | 9.7 × 10² | 0.6 |
| Example 7 | B25 | 4.8 × 10⁻¹⁰ | 3.5 × 10⁻⁷ | 7.3 × 10² | 0.4 |
| Example 8 | B33 | 1.8 × 10⁻¹⁰ | 3.3 × 10⁻⁷ | 1.8 × 10³ | 0.4 |
| Example 9 | B34 | 5.0 × 10⁻¹⁰ | 3.4 × 10⁻⁷ | 6.8 × 10² | 0.3 |
| Compar- | H1 | 7.5 × 10⁻¹⁰ | 2.5 × 10⁻⁷ | 3.3 × 10² | 0.5 |
| ative | | | | | |
| Example 1 | | | | | |
| Compar- | H2 | 6.3 × 10⁻¹⁰ | 3.0 × 10⁻⁷ | 4.8 × 10² | 0.1 |
| ative | | | | | |
| Example 2 | | | | | |
| Compar- | H3 | 5.5 × 10⁻¹⁰ | 3.2 × 10⁻⁷ | 5.8 × 10² | 0.3 |
| ative | | | | | |
| Example 3 | | | | | |
| Compar- | H4 | 1.8 × 10⁻⁹ | 1.9 × 10⁻⁷ | 1.1 × 10² | 0.9 |
| ative | | | | | |
| Example 4 | | | | | |

TABLE 4

| | HOMO | LUMO |
|---|---|---|
| Compound | [eV] | [eV] |
| 2Ph-BTBT | −5.4 | −1.5 |
| F6-SubPc-OC6F5 | −5.8 | −3.0 |
| C60 | −6.0 | −3.2 |
| dpy-NDI | −7.5 | −4.5 |

### REFERENCE SIGNS LIST

1 Electrode
2 Hole blocking layer
3 Photoelectric conversion layer
4 Electron blocking layer
5 Electrode
6 Substrate

1. A photoelectric conversion device having one or two or more organic layers between two electrodes, wherein at least one of the organic layers comprises a material for a photoelectric conversion device represented by the following general formula (1): 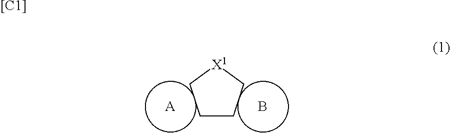
wherein
the ring A and the ring B each independently represent an aromatic group fused with an adjacent ring at any position, and represent a substituted or unsubstituted fused aromatic hydrocarbon group having 8 to 20 carbon atoms, or a substituted or unsubstituted fused aromatic heterocyclic group having 10 to 20 carbon atoms,
X¹ represents C (Ar¹Ar²), N—Ar³, O, or S,
Ar¹ to Ar³ each independently represent hydrogen, deuterium, a cyano group, a halogen, a nitro group, an alkyl group having 1 to 20 carbon atoms, an aralkyl group having 7 to 38 carbon atoms, an alkenyl group having 2 to 20 carbon atoms, an alkynyl group having 2 to 20 carbon atoms, an acyl group having 2 to 20 carbon atoms, an acyloxy group having 2 to 20 carbon atoms, an alkoxy group having 1 to 20 carbon atoms, an alkoxycarbonyl group having 2 to 20 carbon atoms, an alkoxycarbonyloxy group having 2 to 20 carbon atoms, an alkylsulfonyl group having 1 to 20 carbon atoms, a substituted or unsubstituted aromatic hydrocarbon group having 6 to 18 carbon atoms, a substituted or unsubstituted aromatic heterocyclic group having 3 to 18 carbon atoms, or a substituted or unsubstituted linked aromatic group in which 2 to 6 of these aromatic groups are linked.

2. The photoelectric conversion device according to claim 1, wherein, in the general formula (1), the ring A is a group represented by general formula (2) and the ring B is a group represented by general formula (3): 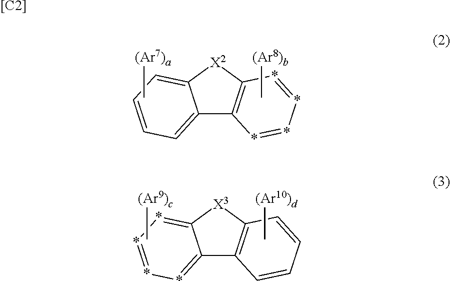
wherein any side represented by “*” represents a position of fusion with an adjacent ring,
X² and X³ each independently represent C (Ar⁴Ar⁵), N—Ar⁶, O, or S,
Ar⁴ to Ar⁶ are each independently the same as defined for Ar¹ to Ar³,
Ar⁷ to Ar¹⁰ each independently represent deuterium, a cyano group, a halogen, a nitro group, an alkyl group having 1 to 20 carbon atoms, an aralkyl group having 7 to 38 carbon atoms, an alkenyl group having 2 to 20 carbon atoms, an alkynyl group having 2 to 20 carbon atoms, an acyl group having 2 to 20 carbon atoms, an acyloxy group having 2 to 20 carbon atoms, an alkoxy group having 1 to 20 carbon atoms, an alkoxycarbonyl group having 2 to 20 carbon atoms, an alkoxycarbonyloxy group having 2 to 20 carbon atoms, an alkylsulfonyl group having 1 to 20 carbon atoms, a substituted or unsubstituted aromatic hydrocarbon group having 6 to 18 carbon atoms, a substituted or unsubstituted aromatic heterocyclic group having 3 to 18 carbon atoms, or a substituted or unsubstituted linked aromatic group in which 2 to 6 of these aromatic groups are linked,
a to d represent the number of substitutions, a and d each independently represent an integer of 0 to 4, and b and c each independently represent an integer of 0 to 2.

3. The photoelectric conversion device according to claim 2, wherein the general formula (1) is represented by any of the following formulae (4) to (24): 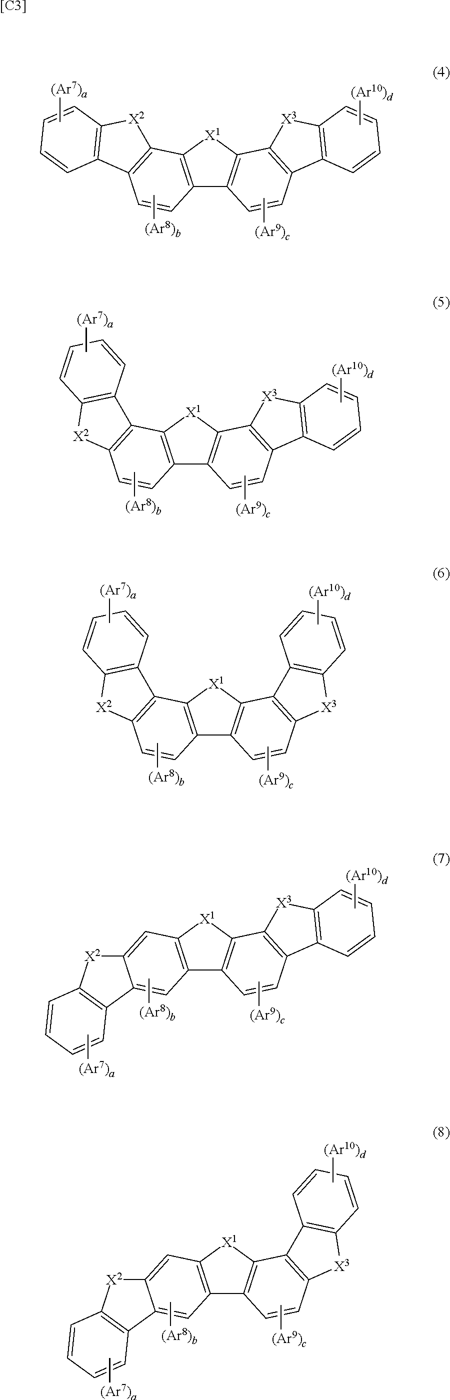 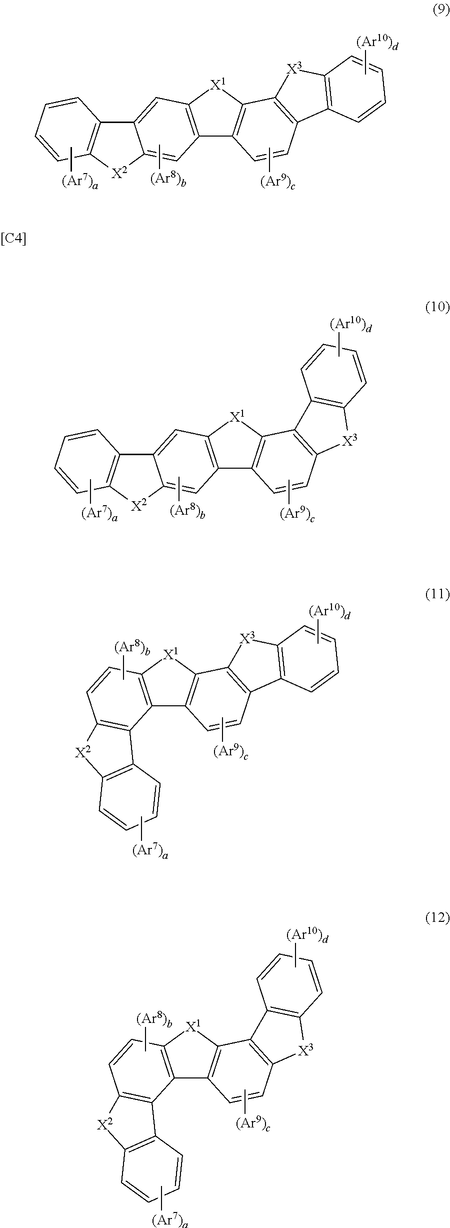 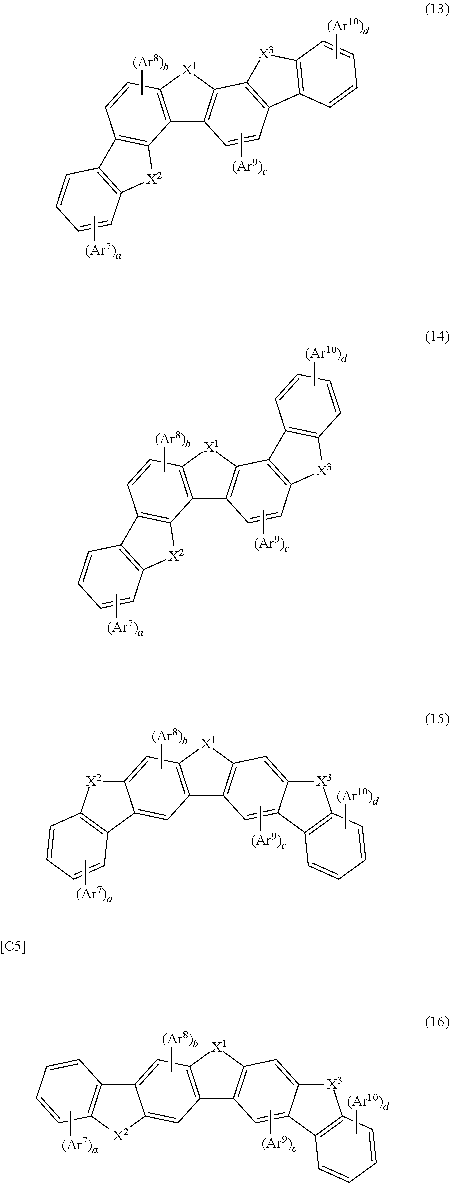 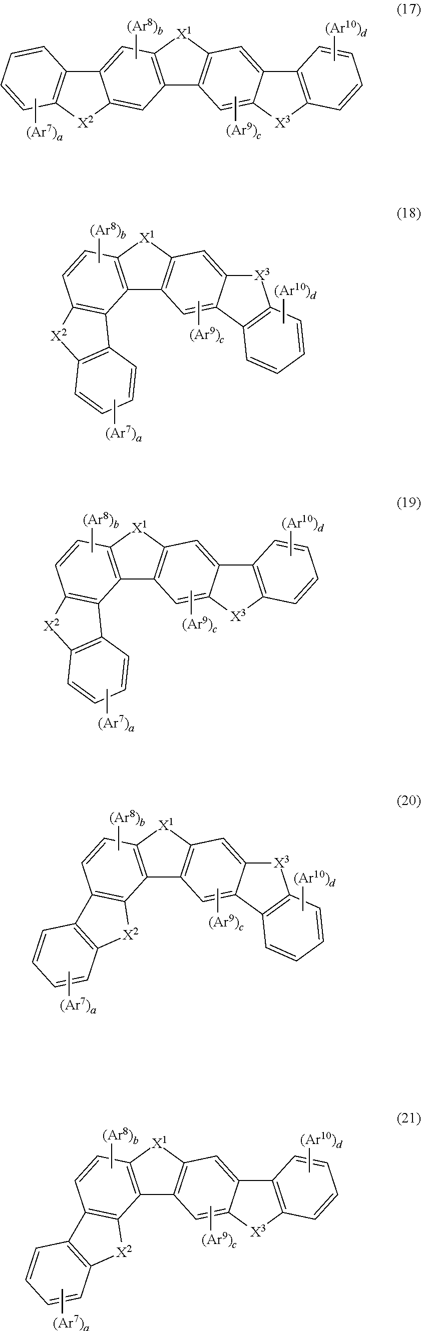 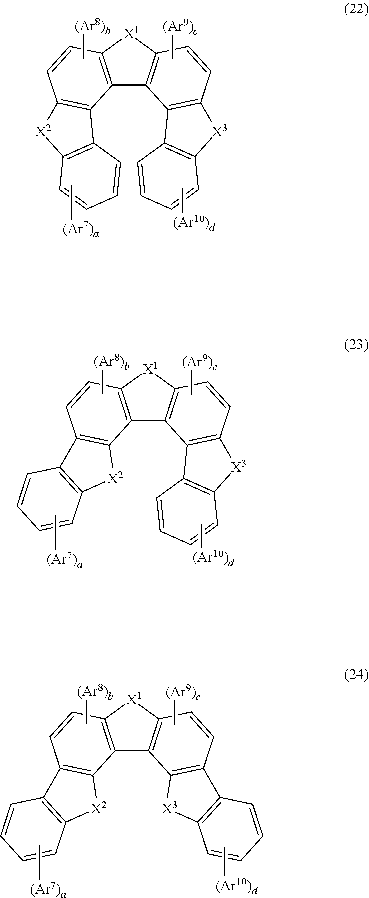
wherein X¹ to X³, Ar⁷ to Ar¹⁰, and a to d are as defined for the general formulae (1) to (3).

4. The photoelectric conversion device according to claim 2, wherein X¹ to X³ in the general formula (1) are represented by N—Ar³, N—Ar⁶, O, or S.

5. The photoelectric conversion device according to claim 2, wherein at least one of X¹ to X³ in the general formula (1) is represented by N—Ar³ or N—Ar⁶.

6. The photoelectric conversion device according to claim 2, wherein Ar³ and Ar⁶ in the general formula (1) are each a substituted or unsubstituted aromatic hydrocarbon group having 6 to 18 carbon atoms, a substituted or unsubstituted electron-donating aromatic heterocyclic group, or a linked aromatic group in which these groups are linked.

7. The photoelectric conversion device according to claim 5, wherein all of X¹ to X³ in the general formula (1) are represented by N—Ar³ or N—Ar⁶.

8. The photoelectric conversion device according to claim 1, wherein the material for a photoelectric conversion device represented by the general formula (1) has an energy level of highest occupied molecular orbital (HOMO) obtained by structural optimization calculation with a density functional calculation B3LYP/6-31G(d) of −4.0 eV or less.

9. The photoelectric conversion device according to claim 1, wherein the material for a photoelectric conversion device represented by the general formula (1) has an energy level of lowest unoccupied molecular orbital (LUMO) obtained by structural optimization calculation with a density functional calculation B3LYP/6-31G(d) of −2.5 eV or more.

10. The photoelectric conversion device according to claim 1, wherein the material for a photoelectric conversion device represented by the general formula (1) has a hole mobility of 1×10⁻⁶ cm²/Vs or more.

11. The photoelectric conversion device according to claim 1, wherein the material for a photoelectric conversion device represented by the general formula (1) is amorphous.

12. The photoelectric conversion device according to claim 1, wherein the material for a photoelectric conversion device represented by the general formula (1) is used as a hole transport material of a photoelectric conversion device for imaging.

13. The photoelectric conversion device according to claim 1, wherein the photoelectric conversion device is a photoelectric conversion device for imaging, comprising a photoelectric conversion layer and an electron blocking layer as organic layers between two electrodes, the electron blocking layer containing the material for a photoelectric conversion device represented by the general formula (1).

14. The photoelectric conversion device according to claim 13, wherein the electron blocking layer contains the material for a photoelectric conversion device.

15. The photoelectric conversion device according to claim 13, wherein the photoelectric conversion layer contains an electron transport material.

16. The photoelectric conversion device according to claim 13, wherein the electron blocking layer contains the material for a photoelectric conversion device, and the photoelectric conversion layer contains a fullerene derivative.
